(19) United States
(12) Patent Application Publication
(10) Pub. No.: US 2007/0241457 A1
(43) Pub. Date: Oct. 18, 2007

(54) Semiconductor apparatus and method of producing the same

(75) Inventor: Tohru Ida, Kashihara-shi (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka (JP)

(21) Appl. No.: 11/783,512

(22) Filed: Apr. 10, 2007

(30) Foreign Application Priority Data
Apr. 14, 2006 (JP) 2006-112779
Dec. 21, 2006 (JP) 2006-345014

(51) Int. Cl. H01L 23/48

(52) U.S. Cl. 257/738

(57) ABSTRACT

A semiconductor apparatus including: a semiconductor substrate having a through hole; an electrode pad provided on a first surface of the semiconductor substrate so as to cover the through hole; an external connection terminal provided on a second surface of the semiconductor substrate; a conductive wiring passing through the through hole and allowing conduction between the electrode pad and an external connection terminal; a first insulating film provided on the first surface of the semiconductor substrate; and a second insulating film provided on a second surface of the semiconductor substrate and on an inner surface of the through hole to insulate the semiconductor substrate from the conductive wiring; the conductive wiring being connected to the electrode pad via the connection opening formed in at least one of the first insulating film and the second insulating film that are formed in such a way that at least a part of the first insulating film and a part of the second insulating film overlap, in a direction vertical to the first surface of the semiconductor substrate, the bottom surface of the through hole, and the connection opening being formed so as to avoid a periphery of the bottom surface of the through hole. This provides a semiconductor apparatus with a highly-reliable through electrode and a method of producing the apparatus.

This Nonprovisional application claims priority under 35 U.S.C. § 119(a) on Patent Applications No. 112779/2006 filed in Japan on Apr. 14, 2006, and No. 345014/2006 filed in Japan on Dec. 21, 2006, the entire contents of which are hereby incorporated by reference.

### FIELD OF THE INVENTION

The present invention relates to a semiconductor apparatus and a method of producing the semiconductor apparatus. Particularly, the present invention relates to a semiconductor apparatus including a conductive wiring suitably isolated with an insulating film, and a method of producing the semiconductor apparatus.

### BACKGROUND OF THE INVENTION

Demands for smaller and thinner semiconductor apparatus have been increasing in recent years. Laminates of a plurality of semiconductor apparatuses have been widely employed to increase mounting density. In response to such demands, for example the technique disclosed in Patent Document 1 (Japanese Unexamined Patent Publication No. 2003-309221; publication date: Oct. 31, 2003) has drawn attention. With the technique, a through electrode is formed through a semiconductor substrate, from an electrode pad formed on a front surface of a semiconductor apparatus to a rear surface of the semiconductor apparatus.

Patent Document 1 discloses a method of producing a BGA (Ball Grid Array) type semiconductor apparatus having a through electrode. In Patent Document 1, the through hole is formed from a rear surface of a semiconductor substrate to an electrode formed on a front surface of the semiconductor substrate. Then, an oxide film is formed by CVD (Chemical Vapor Deposition) on an inner wall of the through hole and on a rear surface of the electrode. Thereafter, anisotropic etching is performed on the oxide film adhered to the rear surface of the electrode.

Further, demands for smaller and thinner miniaturized camera modules, exemplified by mobile phones, have been increasing in recent years.

For example Non-patent Document 1 (The 2004 International Conference on Solid State Devices and Materials, Tokyo, 2004, pp. 276-277) reports that a through electrode and a method of producing a through electrode are applied to a CCD (charge coupled device), the CCD is assembled to form a camera module, and the camera module is installed into a mobile phone. Non-patent Document 1 reports evaluation results of functions thereof.

According to Non-patent Document 1, an electrode pad, a first insulating film, and a second insulating film are formed. The electrode pad is on a first surface of a semiconductor substrate, on which first surface a device is mounted. The first insulating film electrically isolates the electrode pad and the semiconductor substrate from each other. The second insulating film is formed, after a through hole is formed in the semiconductor substrate from a rear surface of a wafer to the electrode pad on a surface of the wafer, to electrically isolate the semiconductor substrate and a conductive wiring that is made of a conductive material and is inside of the through hole from each other. The second insulating film covers a side surface of the through hole and a bottom surface of the through hole. Thereafter, a contact is formed to electrically connect the conductive wiring and the electrode pad in the through hole. Concretely, anisotropic dry etching, specifically Reactive Ion Etching (RIE), is carried out as vertically as possible to eliminate the second insulating film covering the rear surface of the semiconductor substrate, the side surface of the through hole, and the rear surface of the electrode pad provided on the bottom surface of the through hole. As such, the second insulating film formed on the rear surface of the semiconductor substrate and the side surface of the through hole remain, and the second insulating film formed on the bottom surface (the bottom surface corresponds to the rear of the electrode pad) of the through hole is eliminated, thereby allowing only the rear part of the electrode pad to be revealed and forming the contact.

As the foregoing discusses, a semiconductor apparatus having a through electrode and a method of forming the through electrode have drawn attention to realize smaller and thinner devices of wide variety, including CCDs as well as memories.

The following describes concretely the method of forming the through electrode, with reference to FIG. 16.

FIG. 16(a) to FIG. 16(c) are sectional views of the vicinity of the electrode in respective steps of producing the semiconductor apparatus having the through electrode. As shown in FIG. 16(c), generally, a first insulating film 102 is formed on a first surface (front surface) of a semiconductor substrate (semiconductor wafer) 101. A multi-level metal wiring layer is formed on the first insulating film 102. The metal wiring layer includes an electrode pad 103 for the semiconductor apparatus to receive and supply a signal. The through electrode is formed in an area where the electrode pad 103 is formed. A protection film 104 made of an oxide film or a nitride film is formed on the metal wiring layer. A through hole is formed immediately above the electrode pad 103 on the semiconductor substrate 101. A second insulating film 105 is formed to cover a side surface of the through hole, a bottom surface of the through hole, and a second surface (rear surface) of the semiconductor substrate 101. A conductive layer 106 is formed from the bottom surface of the through hole to the second surface of the semiconductor substrate 101. The conductive layer 106 inside of the through hole functions as the through electrode. A protection film 108 protects the second surface of the semiconductor substrate 101. Only a part of the conductive layer 106 is revealed, on which part an external connection terminal 107 is to be mounted, whereby the conductive layer 106 on the second surface of the semiconductor substrate 101 is connected to the external connection terminal 107. As a result, the electrode pad 103 on the first surface of the semiconductor substrate 101 and the external connection terminal 107 on the second surface are electrically connected via the conductive layer 106.

In producing the semiconductor apparatus shown in FIG. 16(c), the second insulating film 105 is formed, by CVD for example, on the second surface of the semiconductor substrate 101 provided with the first insulating film 102, the electrode pad 103, and the protection film 104. In this case, however, the second insulating film 105 is also formed on the rear surface of the electrode pad 103 as shown in FIG. 16(a), which rear surface needs to be electrically connected by the through electrode. Therefore, before the conductive layer 106 is formed, it is necessary to eliminate the second insulating film 105 formed on the rear surface of the electrode pad 103 while leaving the second insulating film 105 formed on the side surface of the through hole as shown in FIG. 16(b).

Several ways are available to eliminate the second insulating film 105 formed on the rear surface of the electrode pad.

A first way is as follows. Resist is applied to the rear surface of the semiconductor substrate 101, the resist inside of the through hole is eliminated by photolithography, and then the second insulating film 105 formed on the rear surface of the electrode pad 103 is eliminated by dry etching. A second way is as follows. Anisotropic dry etching is employed to etch only the second insulating film 105 formed on the rear surface of the electrode pad 103 without etching the second insulating film 105 formed on the side surface of the through hole. Patent Document 1 and Non-patent Document 1 employ the second way.

However, a semiconductor apparatus employing this conventional through electrode and a method of producing the through electrode have a problem that steps that are difficult to control and extremely complicated are required to form a through electrode that is highly insulative.

For example, the first way has a problem that, when the resist is applied evenly to the second surface of the semiconductor substrate having the through hole, it is difficult to bury the resist evenly into the through hole.

Generally, electrodes of the semiconductor apparatus are approximately 100 μm square or below. A thickness of the semiconductor substrate varies. A semiconductor substrate having a thickness of approximately 100 to 800 μm is popularly employed. For example, when a through hole of 70 μm square is formed in a semiconductor substrate having a thickness of 200 μm, it is difficult to apply the resist evenly into this very small through hole. Even if the resist is buried evenly in the through hole, it is difficult to eliminate the resist in the through hole by developing because, with the hole of this aspect ratio, developing fluid flown into the hole is less likely to circulate.

On the other hand, use of the second way is considered to facilitate eliminating the second insulating film formed on the rear surface of the electrode pad, compared to the first way. However, there is a problem that, when the second insulating film is formed by forming an oxide film inside of the through hole by CVD, the second insulating film formed on the side surface of the through hole becomes thinner than the second insulating film formed on the second surface of the semiconductor substrate. Another problem is that, when anisotropic etching is carried out on the second insulating film formed on the rear surface of the electrode pad, the second insulating film formed on the second surface of the semiconductor substrate is higher in etching rate than the second insulating film formed on the rear surface of the electrode pad. In this case, the insulating film formed on the second surface of the semiconductor substrate is also etched. Moreover, even with anisotropic etching, it is not avoidable that the second insulating film formed on the side surface of the through hole decreases as a result of etching. Furthermore, if a barrier metal or a seed metal needs to be formed by PVD before a conductive wiring is formed in a following step, the side surface of the through hole needs to be tilted. This has a problem that, even with anisotropic etching, the second insulating film formed on the side surface of the through hole decreases as a result of etching, and the side surface of the through hole of the semiconductor substrate is likely to be revealed. Further, as shown in FIG. 17, when the vicinity of the bottom surface of the through hole of the semiconductor substrate 101 is tilted further, the second insulating film 105 formed on the side surface of the through hole (especially the second insulating film formed on the slope) decreases further by etching. Consequently, a problem arises that the semiconductor substrate 101 at the side surface of the through hole is revealed.

Accordingly, with the second way, the second insulating film formed on the bottom surface of the through hole needs to be thinner than the second insulating film formed on the second surface of the semiconductor substrate and on the side surface of the through hole. This makes it necessary to form the second insulating films in piles for a plurality of times while changing conditions in formation, and form the second insulating film on the second surface of the semiconductor substrate and on the side surface of the through hole in such a way as to be thicker than the second insulating film formed on the bottom surface of the through hole. Alternatively, it is necessary to eliminate the second insulating film formed on the rear surface of the electrode pad by etching and then form the second insulating film again on the second surface of the semiconductor substrate.

Further, with this conventional method, a depression generally called a notch 131 may be formed, as shown in FIGS. 18(a) to 18(c), in forming the through hole by anisotropic etching, more specifically, Reactive Ion Etching (RIE). As shown in FIG. 18(a), when the through hole is formed by the conventional method, a resist film 112 is formed on the semiconductor substrate 101. Then, the through hole to the electrode pad 103 is formed by anisotropic etching with the use of the resist film 112. At this time, in the through hole, the notch 131 is formed in a part of the semiconductor substrate 101, which part is in contact with the first insulating film 102. When the second insulating film 105 is formed by CVD thereafter, the second insulating film is not formed sufficiently in the notch 131 as shown in FIG. 18(b). With the semiconductor substrate being in this state, if the conductive layer 106 is formed on the semiconductor substrate as shown in FIG. 18(c), leakage occurs in between the semiconductor substrate 101 and the conductive layer 106. To avoid the leakage, etching conditions need to be changed at each step in carrying out the etching. Accordingly, with the conventional method, after extremely complicated processes are carried out, a part of the rear surface of the electrode pad is eventually revealed to make conduction between the electrode pad and the conductive wiring. Specifically, the through hole is formed while changing etching conditions, and, in forming the second insulating film to cover the inner wall of the through hole and the second surface of the semiconductor substrate, films are formed for a plurality of times while changing film-forming conditions.

Accordingly, this method of eliminating the oxide film formed on the rear surface of the electrode pad by anisotropic etching requires many conditions to be considered in determining process conditions. Examples of the conditions to be considered include: thickness of the second insulating film formed on the rear surface of the semiconductor substrate; thickness of the second insulating film formed on the side surface of the semiconductor substrate; thickness of the second insulating film formed on the bottom surface of the through hole; and the shape of the tilt of the side surface of the through hole. In other words, the method has a problem that process conditions to be controlled are extremely complicated, which process conditions include various parameters of surfaces of semiconductor substrates, various parameters between semiconductor substrates, various parameters between lots, and changes over time in the state of semiconductor apparatuses.

### SUMMARY OF THE INVENTION

The present invention has as an object to provide a semiconductor apparatus employing a highly reliable through electrode, and a method of producing the semiconductor apparatus.

To attain the object, a semiconductor apparatus of the present invention is adapted so that the semiconductor apparatus includes: a semiconductor substrate having a through hole formed through both surfaces of the semiconductor substrate; an electrode pad provided, on a first surface of the semiconductor substrate, so as to cover the through hole; an external connection terminal provided on a second surface of the semiconductor substrate; a conductive wiring passing through the through hole and allowing conduction between the electrode pad and the external connection terminal; a first insulating film provided on the first surface of the semiconductor substrate to insulate the semiconductor substrate from the electrode pad; and a second insulating film provided on the second surface of the semiconductor substrate and on an inner surface of the through hole to insulate the semiconductor substrate from the conductive wiring, the conductive wiring being connected to the electrode pad via a connection opening formed in at least one of the first insulating film and the second insulating film that are provided in such a way that at least a part of the first insulating film and a part of the second insulating film overlap, in a direction vertical to the first surface of the semiconductor substrate, a bottom surface of the through hole, and the connection opening being formed in such a way as to avoid a periphery of the bottom surface of the through hole.

With this structure, the inner side surface of the through hole is covered by the second insulating film, and the second insulating film insulates the conductive wiring and the semiconductor substrate from each other. This prevents the inner side surface of the through hole of the semiconductor substrate from exposing. Therefore, insulation between the conductive wiring and the semiconductor substrate in the through hole is prevented from deteriorating, so that leakage due to deterioration in the insulation is prevented. Further, with the structure, only the insulating film on the bottom surface of the through hole is eliminated even when the side surface of the through hole is formed at an angle of 90 degrees with respect to the bottom surface of the through hole. This allows the semiconductor apparatus to be reduced in size.

To attain the above object, the method of producing a semiconductor apparatus in accordance with the present invention is adapted so that the method includes the steps of: forming an electrode pad on a first surface of a semiconductor substrate via a first insulating film; forming a through hole in the semiconductor substrate from a second surface, which is positioned opposite to the first surface, of the semiconductor substrate to the electrode pad formed on the first surface; forming a second insulating film on a side surface of the through hole, on a bottom surface of the through hole, and on the second surface of the semiconductor substrate to insulate the semiconductor substrate from a conductive wiring; eliminating the second insulating film formed so as to overlap the bottom surface of the through hole, and forming a connection opening to the electrode pad in such a way as to avoid a periphery of the bottom surface of the through hole; and forming the conductive wiring to electrically connect the electrode pad to an external connection terminal.

With this structure, only a part of the second insulating film placed on the bottom surface of the through hole is eliminated, which part is not in contact with a periphery of the bottom surface of the through hole. The part from which the second insulating film is eliminated is used as a connection opening. This assures that the connection opening is surrounded by the second insulating film. This allows the conductive wiring and the semiconductor substrate to be isolated from each other.

Further, to attain the above object, the method of producing a semiconductor apparatus in accordance with the present invention is adapted so that the method includes the steps of: forming an electrode pad on a first surface of a semiconductor substrate via a first insulating film; forming a through hole in the semiconductor substrate from a second surface, which is positioned opposite to the first surface, of the semiconductor substrate to the first insulating film; forming a second insulating film on a side surface of the through hole, on a bottom surface of the through hole, and on the second surface of the semiconductor substrate to insulate the semiconductor substrate from a conductive wiring; forming, on the second insulating film formed on the second surface of the semiconductor substrate, a resist film so as to cover the through hole; forming an etching mask by forming an opening within a part of the resist film, which part overlaps, in a direction vertical to the first surface of the semiconductor substrate, the bottom surface of the through hole; eliminating, by anisotropic dry etching with the etching mask, the first insulating film and the second insulating film that are formed so as to overlap the bottom surface of the through hole, and forming a connection opening to the electrode pad in such a way as to avoid a periphery of the bottom surface of the through hole; and forming the conductive wiring to electrically connect the electrode pad to an external connection terminal.

With this structure, anisotropic dry etching is carried out with the use of a resist film that is in the form of film and has an opening smaller than the bottom surface of the through hole, thereby eliminating the first insulating film and the second insulating film that are placed on top of another on the bottom surface of the through hole. This makes it possible to eliminate only the first insulating film and the second insulating film that are placed on top of another on the bottom surface of the through hole, without eliminating the second insulating film formed on the inner side surface of the through hole. Therefore, the semiconductor substrate at the inner side surface of the through hole is not revealed, and insulation between the conductive wiring and the semiconductor substrate in the through hole is maintained suitably. Further, with the structure, only the insulating film on the bottom surface of the through hole is eliminated even when the side surface of the through hole is formed at an angle of 90 degrees with respect to the bottom surface of the through hole. This allows the semiconductor apparatus to be reduced in size.

Further, to attain the above object, the method of producing a semiconductor apparatus in accordance with the present invention is adapted so that the method includes the steps of: forming an electrode pad on a first surface of a semiconductor substrate via a first insulating film; forming a through hole in the semiconductor substrate from a second surface, which is positioned opposite to the first surface, of the semiconductor substrate to the first insulating film formed on the first surface; forming a second insulating film on a side surface of the through hole, on a bottom surface of the through hole, and on the second surface of the semiconductor substrate to insulate the semiconductor substrate from a conductive wiring; forming, on the second insulating film formed on the second surface of the semiconductor substrate, a resist film so as to cover the through hole; forming an etching mask by forming an opening within a part of the resist film, which part overlaps, in a direction vertical to the first surface of the semiconductor substrate, the bottom surface of the through hole; eliminating, by anisotropic dry etching with the etching mask, the first insulating film formed so as to overlap the bottom surface of the through hole, and forming a connection opening to the electrode pad in such a way as to avoid a periphery of the bottom surface of the through hole; and forming the conductive wiring to electrically connect the electrode pad to an external connection terminal.

With this structure, anisotropic dry etching is carried out with the use of a resist film that is in the form of film and has an opening smaller than the bottom surface of the through hole, thereby eliminating the first insulating film placed on the bottom surface of the through hole. This makes it possible to eliminate only the first insulating film placed on the bottom surface of the through hole, without eliminating the second insulating film formed on the inner side surface of the through hole. Therefore, the semiconductor substrate at the inner side surface of the through hole is not revealed, and insulation between the conductive wiring and the semiconductor substrate in the through hole is maintained suitably. Further, with the structure, only the insulating film on the bottom surface of the through hole is eliminated even when the side surface of the through hole is formed at an angle of 90 degrees with respect to the bottom surface of the through hole. This allows the semiconductor apparatus to be reduced in size.

Further, to attain the above object, the method of producing a semiconductor apparatus in accordance with the present invention is adapted so that the method includes the steps of: forming an electrode pad on a first surface of a semiconductor substrate via a first insulating film; forming a through hole in the semiconductor substrate from a second surface, which is positioned opposite to the first surface, of the semiconductor substrate to the first insulating film formed on the first surface; forming a third insulating film on a side surface of the through hole, on a bottom surface of the through hole, and on the second surface of the semiconductor substrate to insulate the semiconductor substrate from a conductive wiring; forming, on the third insulating film, a photosensitive resin film, for masking, so as to cover the through hole; carrying out photolithography on the photosensitive resin film to form an etching mask having an opening within a part of the etching mask, which part overlaps, in a direction vertical to the first surface of the semiconductor substrate, the bottom surface of the through hole; eliminating, by anisotropic dry etching with the etching mask, a laminate film of the first insulating film and the third insulating film, which laminate film is formed so as to overlap the bottom surface of the through hole, and forming an opening to the electrode pad in such a way as to avoid a periphery of the bottom surface of the through hole; forming, after the etching mask is peeled away, a second insulating film on the third insulating film, the second insulating film being formed of a photosensitive resin film; forming the connection opening to the electrode pad by carrying out, on the second insulating film formed so as to overlap the bottom surface of the through hole, photolithography to eliminate the second insulating film that is not on a periphery of the bottom surface of the through hole; and forming the conductive wiring to electrically connect the electrode pad to an external connection terminal.

With this structure, anisotropic dry etching is carried out by using, as an etching mask, a photosensitive resin film having an opening smaller than the bottom surface of the through hole, thereby eliminating the laminate film constituted of the first insulating film and the third insulating film and placed on the bottom surface of the through hole. Further, with the structure, the second insulating film is formed with the use of the photosensitive resin film. This makes it possible to form the second insulating film having a desired opening, without eliminating the third insulating film formed on the inner side surface of the through hole. Therefore, the semiconductor substrate at the inner side surface of the through hole is not revealed, and insulation between the conductive wiring and the semiconductor substrate in the through hole is maintained suitably. Further, with the structure, only the insulating film on the bottom surface of the through hole is eliminated even when the side surface of the through hole is formed at an angle of 90 degrees with respect to the bottom surface of the through hole. This allows the semiconductor apparatus to be reduced in size.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a sectional view showing a structure of a main part of a semiconductor apparatus in accordance with an embodiment of the present invention.

FIG. 2 is a sectional view showing a structure of a main part of a semiconductor apparatus in accordance with another embodiment of the present invention.

FIG. 3 is a sectional view showing a structure of a main part of a semiconductor apparatus in accordance with another embodiment of the present invention.

FIG. 4 is a sectional view showing a structure of a main part of a CCD package in accordance with another embodiment of the present invention.

FIG. 5 is a sectional view showing a structure of a main part of a CCD package in accordance with another embodiment of the present invention.

FIG. 6 is a sectional view showing a structure of a main part of a CCD package in accordance with another embodiment of the present invention.

FIGS. 7(a) to 7(g) are sectional views of the semiconductor apparatus, each showing a part of processes of producing the semiconductor apparatus.

FIGS. 8(a) to 8(g) are sectional views of the semiconductor apparatus, each showing a part of processes of producing the semiconductor apparatus.

FIGS. 9(a) to 9(g) are sectional views of the semiconductor apparatus, each showing a part of processes of producing the semiconductor apparatus.

FIG. 10(a) to 10(c) are sectional views showing how a resist film is formed in accordance with another embodiment of the present invention.

FIGS. 11(a) to 11(g) are sectional views of the CCD package, each showing a part of processes of producing the CCD package.

FIGS. 12(a) to 12(d) are sectional views of the semiconductor apparatus provided with a barrier metal layer and a seed metal layer, showing a part of processes of producing the semiconductor apparatus.

FIGS. 13(a) to 13(d) are sectional views of the semiconductor apparatus provided with a barrier metal layer and a seed metal layer, showing a part of processes of producing the semiconductor apparatus.

FIGS. 14(a) to 14(d) are sectional views of the semiconductor apparatus provided with a barrier metal layer and a seed metal layer, showing a part of processes of producing the semiconductor apparatus.

FIGS. 15(a) to 15(d) are sectional views of the CCD package provided with a barrier metal layer and a seed metal layer, showing a part of processes of producing the CCD package.

FIGS. 16(a) to 16(c) are sectional views showing how a first insulating film and a second insulating film of a conventional semiconductor apparatus are formed.

FIG. 17 is a sectional view showing how a first insulating film and a second insulating film of a conventional semiconductor apparatus are formed.

FIGS. 18(a) to 18(c) are sectional views of a semiconductor substrate in a conventional process of producing the semiconductor apparatus. FIG. 18(a) is a sectional view showing a state immediately after a through hole is formed in the semiconductor substrate. FIG. 18(b) is a sectional view showing a state in which a second insulating film is formed. FIG. 18(c) is a sectional view showing a state in which a conductive wiring is formed after the second insulating film formed on a bottom surface of the through hole is eliminated by anisotropic etching.

FIGS. 19(a) to 19(g) are sectional views of the semiconductor apparatus, each showing a part of processes of producing the semiconductor apparatus.

FIG. 20 is a sectional view showing a structure of a main part of a semiconductor apparatus in accordance with another embodiment of the present invention.

FIGS. 21(a) to 21(d) are sectional views of the semiconductor apparatus, each showing a part of processes of producing the semiconductor apparatus.

FIGS. 22(a) to 22(e) are sectional views of the semiconductor apparatus, each showing a part of processes of producing the semiconductor apparatus.

FIG. 23 is a sectional view showing a structure of a main part of a semiconductor apparatus in accordance with another embodiment of the present invention.

FIGS. 24(a) to 24(g) are sectional views of the semiconductor apparatus, each showing a part of processes of producing the semiconductor apparatus.

FIGS. 25(a) to 25(e) are sectional views of the semiconductor apparatus, each showing a part of processes of producing the semiconductor apparatus.

FIG. 26 is a sectional view showing a structure of a main part of a semiconductor apparatus in accordance with another embodiment of the present invention.

FIGS. 27(a) to 27(g) are sectional views of the semiconductor apparatus, each showing a part of processes of producing the semiconductor apparatus.

FIGS. 28(a) to 28(e) are sectional views of the semiconductor apparatus, each showing a part of processes of producing the semiconductor apparatus.

FIG. 29 is a sectional view showing a structure of a main part of a CCD package in accordance with another embodiment of the present invention.

FIG. 30 is a sectional view showing a structure of a main part of a CCD package in accordance with another embodiment of the present invention.

FIG. 31 is a sectional view showing a structure of a main part of a CCD package in accordance with another embodiment of the present invention.

FIGS. 32(a) to 32(d) are sectional views of the CCD package, showing a part of processes of producing the CCD package.

FIGS. 33(a) to 33(e) are sectional views of the CCD package, showing a part of processes of producing the CCD package.

FIGS. 34(a) to 34(g) are sectional views of the CCD package, showing a part of processes of producing the CCD package.

FIGS. 35(a) to 35(e) are sectional views of the CCD package, showing a part of processes of producing the CCD package.

FIGS. 36(a) to 36(g) are sectional views of the CCD package, showing a part of processes of producing the CCD package.

FIGS. 37(a) to 37(e) are sectional views of the CCD package, showing a part of processes of producing the CCD package.

### DESCRIPTION OF THE EMBODIMENTS

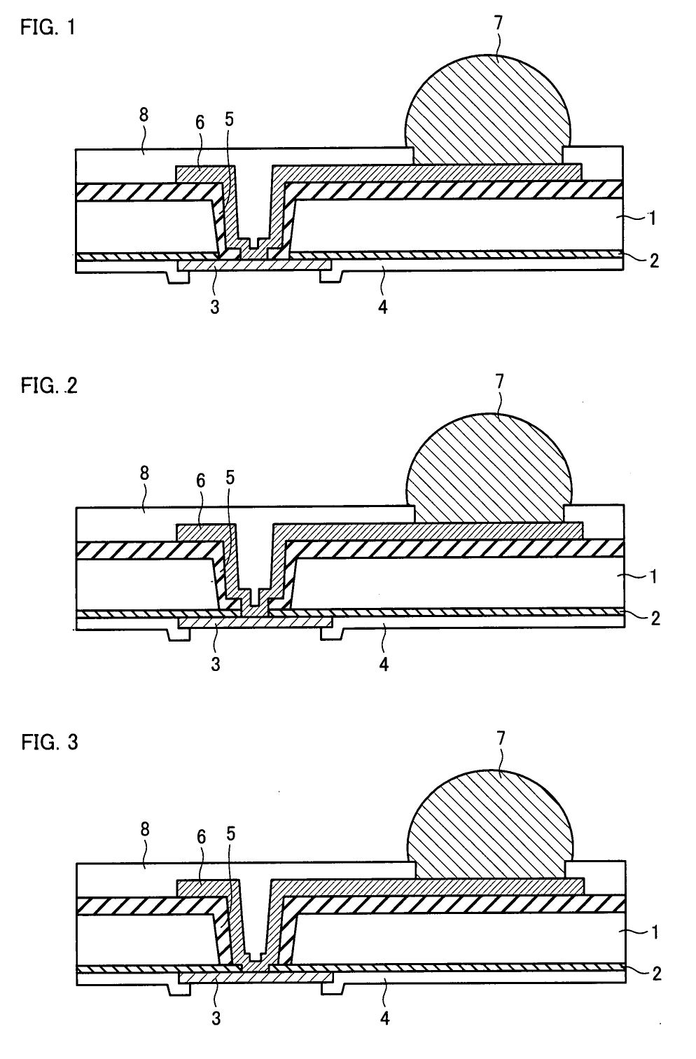

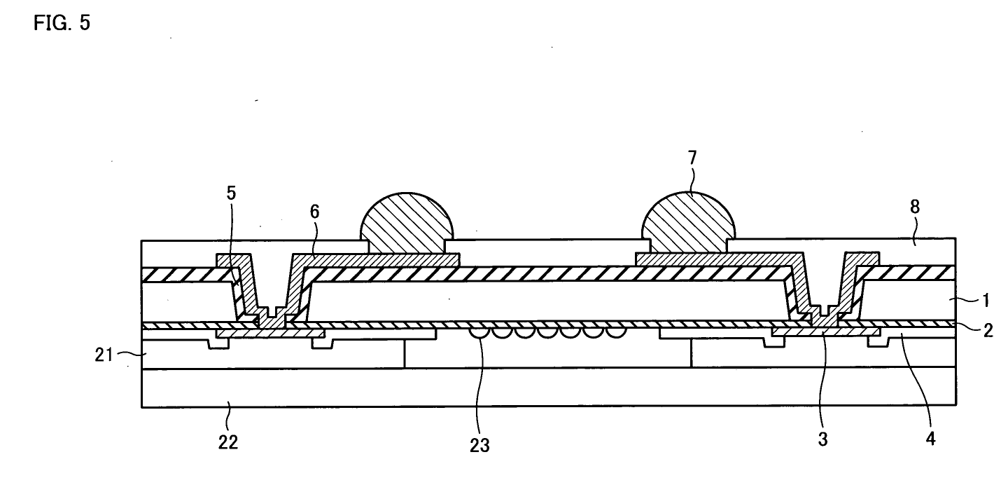

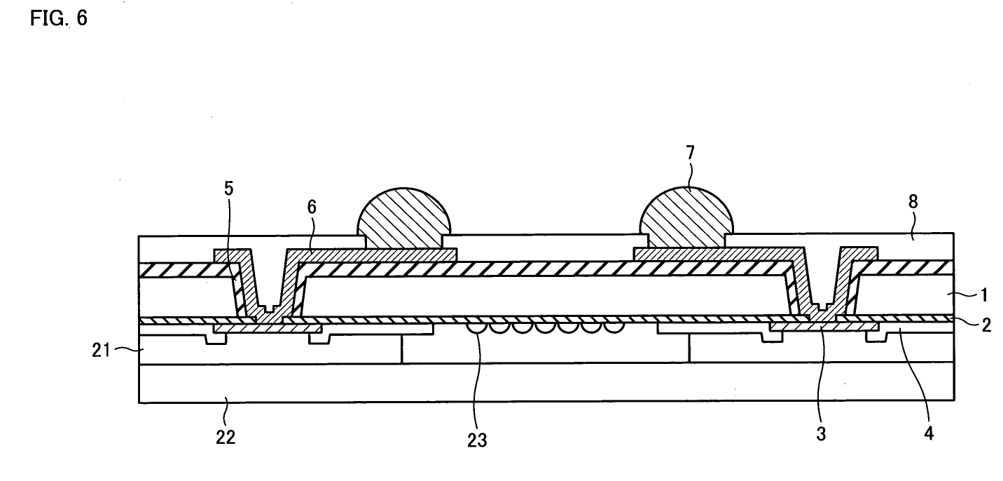

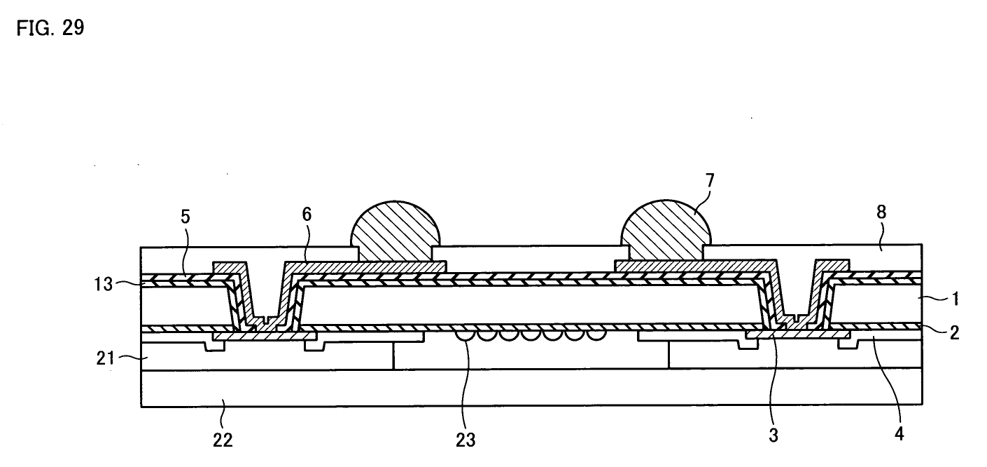

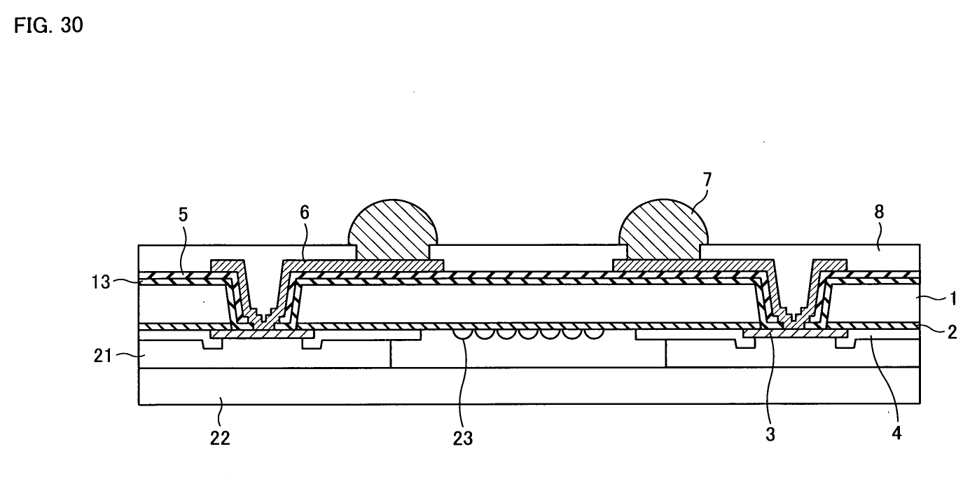

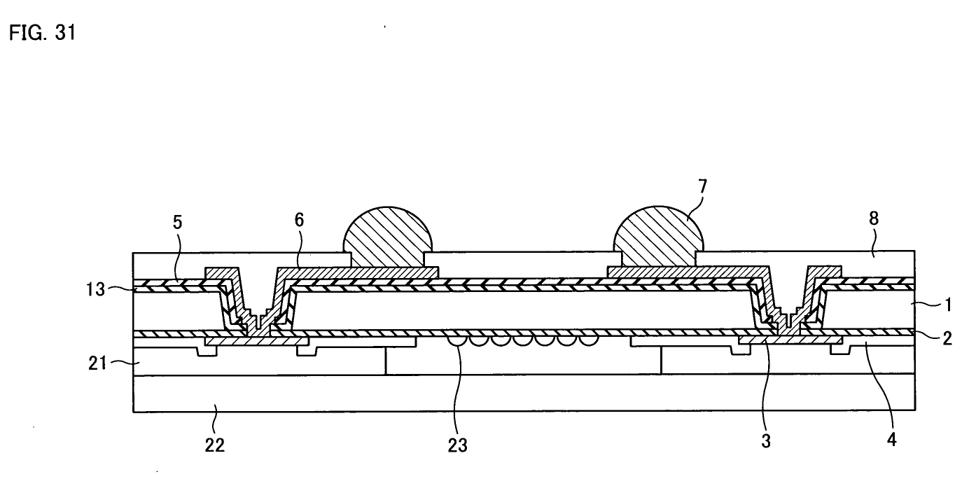

The following describes an embodiment of the present invention, with reference to FIGS. 1 to 15 and FIGS. 19 to 37.

### Embodiment 1

FIG. 1 is a cross section showing a structure of the vicinity of an electrode section of a semiconductor apparatus in accordance with the present embodiment.

As shown in FIG. 1, in the semiconductor apparatus of the present embodiment, a metal wiring layer of single-layer or multi-layer (generally multi-layer) is formed on a first surface (front surface) of a semiconductor substrate 1 via a first insulating film 2. Although not shown in the figure, a semiconductor device is connected to a predetermined terminal on the metal wiring layer. An electrode pad 3 is formed for the semiconductor device to receive and supply a signal. FIG. 1 only shows the electrode pad 3, which is included in the metal wiring layer. A protection film 4 made of an oxide film or a nitride film is formed on the metal wiring layer. Materials of the semiconductor substrate 1 are not particularly limited, and any publicly-known substrates may be used. For example a Si-substrate or a GaAs-substrate may be used. Further, materials of the first insulating film 2 are not particularly limited, and any publicly-known insulating films may be used. It is preferable that the insulating film be formed of, for example, a Si oxide film, an oxide film containing boron or phosphorus, a Si oxinitride film, a Si nitride film, or a laminated film of the foregoing films. Use of an oxide film such as a Si oxide film is more preferable.

In the semiconductor apparatus of the present embodiment, the through electrode is formed in an area where the electrode pad 3 is formed. Accordingly, in the semiconductor substrate 1, a through hole is formed immediately above the electrode pad 3. A second insulating film 5 is formed to cover an inside (side surface and bottom surface) of the through hole and a second surface (rear surface) of the semiconductor substrate 1. It is preferable that the second insulating film 5 be a Si oxide film, an oxide film containing boron or phosphorus, a Si oxinitride film, a Si nitride film, a laminated film of the foregoing films, a film made of an electrodeposition material, or a photosensitive resin film. It is preferable that the electrodeposition material be polyimide, epoxy resin, acrylic resin, polyamine, or polycarboxylic acid resin. It is preferable that the photosensitive resin film be a film made of polyimide, epoxy resin, acrylic resin, or silicone resin.

The second insulating film 5 is provided in such a way that at least a part of the film 5 overlaps, in a direction vertical to the first surface of the semiconductor substrate 1, the bottom surface of the through hole. A part of the second insulating film 5 is opened. Specifically, this opening in the second insulating film 5 is formed in such a way as to avoid the periphery of the bottom surface of the through hole. The shape of the opening is not particularly limited, as long as the opening is formed in such a way as to avoid the periphery of the bottom surface of the through hole.

A conductive wiring layer 6 (conductive wiring) is formed from the inside of the through hole to the second surface of the semiconductor substrate 1. The conductive wiring layer 6 inside of the through hole functions as the through electrode. The first insulating film 2 and the second insulating film 5 keep the electrode pad 3 and the conductive wiring layer 6 insulated from the semiconductor substrate 1.

The conductive wiring layer 6 formed on the second surface of the semiconductor substrate 1 is connected to an external input/output terminal 7 (external connection terminal). A protection film 8 covers the second surface of the semiconductor substrate 1, and a part of the conductive wiring layer 6 is revealed, on which part the external input/output terminal 7 is to be mounted. This allows conduction to be made between the electrode pad 3 on the first surface of the semiconductor substrate 1 and the external input/output terminal 7 on the second surface via the conductive wiring layer 6.

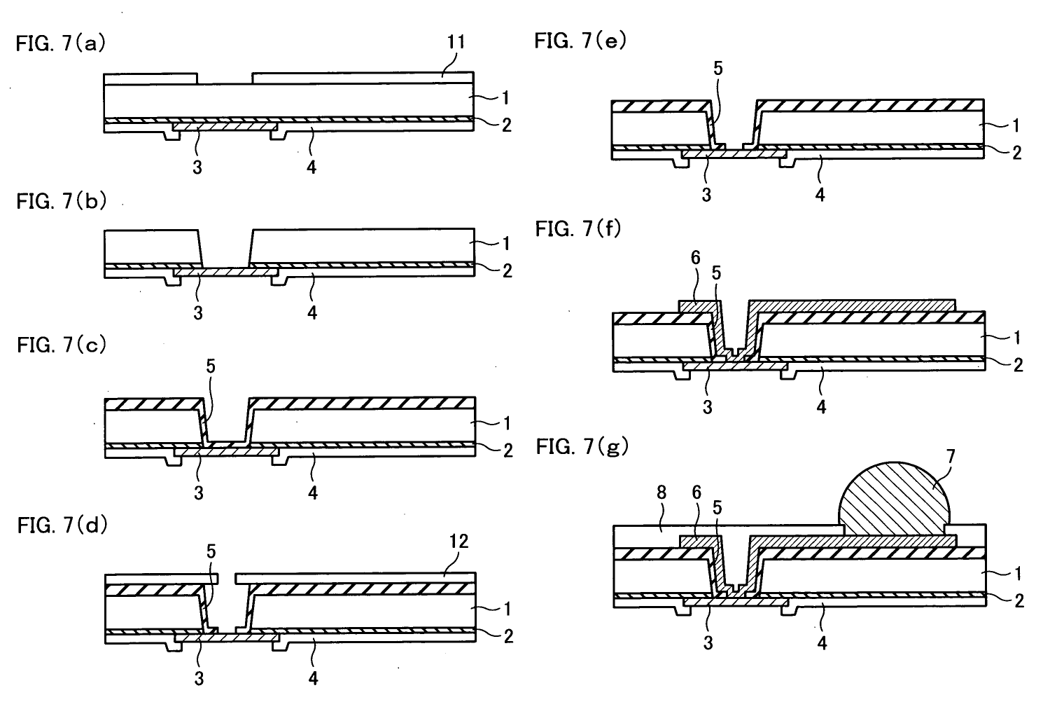

The following describes a method of producing a semiconductor apparatus in accordance with the present embodiment, with reference to FIGS. 7(a) to 7(g). FIGS. 7(a) to 7(g) each show a cross section of a structure in the vicinity of the electrode section in respective steps of producing the semiconductor apparatus of the present embodiment.

First, as shown in FIG. 7(a), a resist film 11 is formed on the second surface of the semiconductor substrate 1. The resist film 11 has an opening for forming a through hole in a following step. The first insulating film 2 is formed on the first surface of the semiconductor substrate 1. The protection film 4 and the metal wiring layer including the electrode pad 3 are formed on the first insulating film 2.

The thickness of the semiconductor substrate 1 is not particularly limited, but it is preferable that the thickness be adjusted to the range of 100 μm to 300 μm by rear-surface polishing. If the semiconductor substrate 1 is too thick, a deep through hole is formed in the semiconductor substrate 1 in a following step. This causes etching time to become longer, which degrades performance, increases costs, and makes it difficult to control the shape of the through hole. Therefore, the semiconductor substrate 1 is made thin to some extent so that an etching depth becomes shallow. On the other hand, if the semiconductor substrate 1 is too thin, handling of the semiconductor substrate 1 becomes difficult in following steps. For example, risk of breakage increases, and bows occur easily. Thus, it is preferable that the thickness of the semiconductor substrate 1 be adjusted to the range of 100 μm to 300 μm. Further, as described above, resist is applied to the second surface (polished surface) of the semiconductor substrate 1. Then, the resist is exposed and developed to open a part of the resist, which part corresponds to the electrode pad 3 on the first surface, thereby forming the resist film 11. The resist film 11 functions as a mask in dry etching carried out to form the through hole in the semiconductor substrate 1. The method of forming the resist film 11 is not particularly limited, and any publicly-known methods may be used. Further, materials of the resist film 11 are not particularly limited, and any publicly-known resist films may be used.

Then, as shown in FIG. 7(b), dry etching is carried out on the semiconductor substrate 1 with the use of the resist film 11 as a mask, thereby forming the through hole. As a result of the dry etching, the semiconductor substrate 1 and the first insulating film 2 immediately above the electrode pad 3 are etched. Consequently, the rear surface of the electrode pad 3 is revealed. After the etching, the resist film 11 is peeled away.

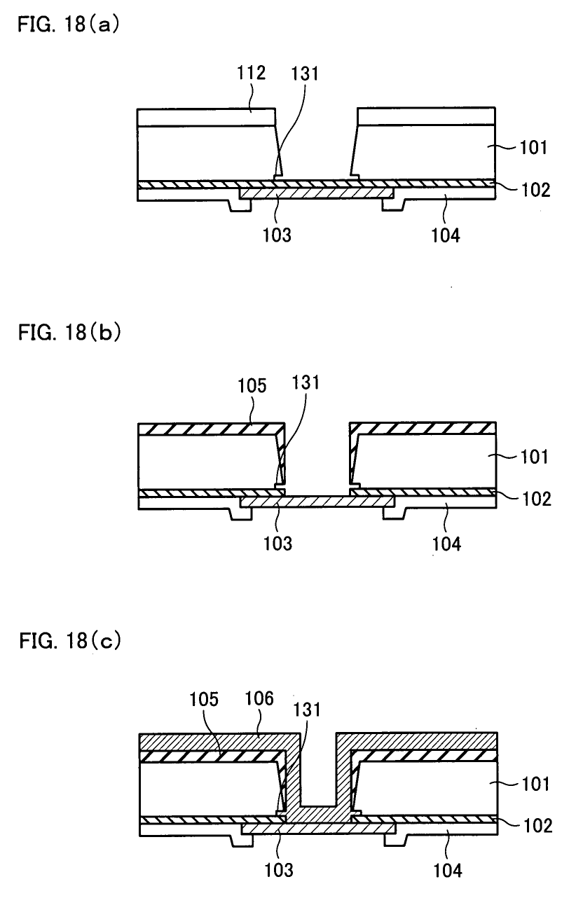

Then, as shown in FIG. 7(c), the second insulating film 5 is formed on the side surface of the through hole, on the rear surface of the electrode pad 3, and on the second surface of the semiconductor substrate 1. It is preferable that the second insulating film 5 be a Si oxide film, an oxide film containing boron or phosphorus, a Si oxinitride film, a Si nitride film, a laminated film of the foregoing films, a film made of an electrodeposition material, or a photosensitive resin film. It is preferable that the electrodeposition material be polyimide, epoxy resin, acrylic resin, polyamine, or polycarboxylic acid resin. It is preferable that the photosensitive resin film be a film made of polyimide, epoxy resin, acrylic resin, or silicone resin. The method of forming the second insulating film 5 is not particularly limited, and any publicly-known method may be employed to form the second insulating film 5. For example if the second insulating film 5 is a Si oxide film, an oxide film containing boron or phosphorus, a Si oxinitride film, a Si nitride film, or a laminated film of the foregoing films, it is preferable to employ plasma CVD to form the second insulating film 5. If the second insulating film is made of an electrodeposition material, it is preferable to employ an electrodeposition-film forming method to form the second insulating film 5. For example in the case in which an electrodeposition material is employed as the second insulating film 5, even if a notch is formed as shown in FIGS. 18(a) to 18(c), the electrodeposition material covers the inside of the notch. This produces an advantage that, even if a conductive wiring layer is formed in the through hole as shown in FIG. 7(f), which will be described below, the conductive wiring layer and the semiconductor substrate are kept insulated.

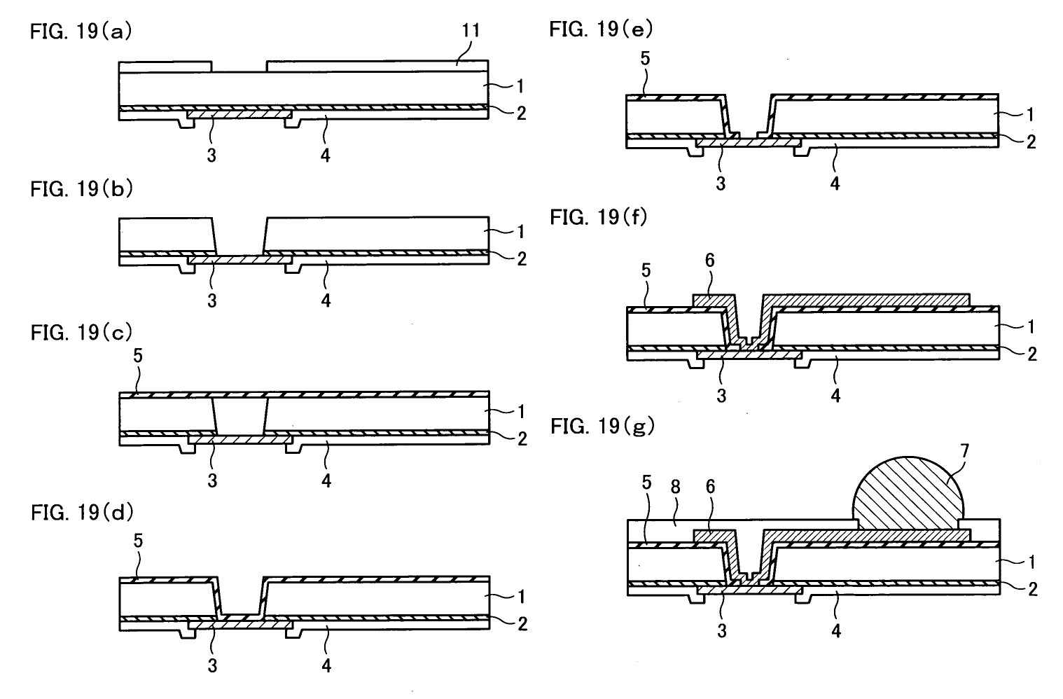

The second insulating film may be formed by, for example, the method shown in FIGS. 19(a) to 19(g). In the case in which the second insulating film is to be formed with this method, the second insulating film 5 is not particularly limited, but it is preferable that the second insulating film 5 be a photosensitive resin film. The photosensitive resin film is not particularly limited, but it is preferable that the photosensitive resin film be a film made of polyimide, epoxy resin, acrylic resin, or silicone resin. When the second insulating film is to be formed with the method, a step of changing the shape of the second insulating film is carried out, which will be described below. It is preferable that the second insulating film be flexible during the step. Use of a photosensitive resin as the second insulating film allows the second insulating film to be flexible, if no light is illuminated thereon before the step. This allows the second insulating film to be adhered closely to the inside of the through hole. If illuminated with light after having been adhered to the inside of the through hole, the second insulating film adhered closely to the inside of the through hole is formed. If a mask is used in illuminating the light on the second insulating film, a desired opening (connection opening) is formed in the second insulating film.

The steps shown in FIGS. 19(a) and 19(b) are same as those shown in FIGS. 7(a) and 7(b). Therefore, description thereof is omitted. To form the second insulating film, first of all, the second insulating film 5 is adhered to the second surface of the semiconductor substrate 1 in such a way as to cover an opening section of the through hole as shown in FIG. 19(c).

Then, as shown in FIG. 19(d), the second insulating film 5 in the shape of a sheet is adhered to the second surface of the semiconductor substrate 1 under reduced pressure, and thereafter pressure is applied. Due to the difference in pressure between the outside (pressure applied) and the inside (pressure reduced) of the through hole, the second insulating film 5 in the shape of a sheet is adhered to the second surface of the semiconductor substrate 1 and to an inner wall of the through hole, thereby forming the second insulating film 5. In this case, it is preferable to apply heat to the second insulating film 5 and to the semiconductor substrate 1 so that it becomes easy to change the shapes of the second insulating film 5 and the semiconductor substrate 1.

The method of creating the difference in pressure between the outside and the inside of the through hole is not particularly limited. For example, a pressure-reduced atmosphere is created with the use of a vacuum laminator. Then, under the pressure-reduced atmosphere, the second insulating film 5 is adhered to the second surface of the semiconductor substrate 1. At this time, the inside of the through hole is closed hermetically and therefore is in a vacuum state. It is preferable at this time that a heat (for example 30° C. to 250° C.) and a pressure (fro example 10K to 20 Mpa) be applied to the semiconductor apparatus by use of a press mechanism to prevent bubbles in between the second insulating film 5 and the second surface of the semiconductor substrate 1. It is preferable that the degree of vacuum inside of the through hole be 100K to 1 Pa. As described above, the second insulating film 5 is adhered to the second surface of the semiconductor substrate 1 under the pressure-reduced atmosphere. Then, a pressure is applied to the outside of the through hole. Methods of applying the pressure are not particularly limited. For example, inert gas such as nitrogen is applied to the outside of the through hole. As a result of application of the pressure, the second insulating film 5 is drawn to the inside of the through hole. Consequently, the second insulating film 5 is adhered to the inside of the through hole.

It is possible to employ this method to form not only the second insulating film 5 but also any other films. In this method, a desired structure is first formed in the shape of a film and then is adhered to another structure. This method therefore allows a film having an even thickness to be formed on a structure having a complicated shape exemplified by the inside of the through hole. In other words, a film having an even thickness is formed on any part of the structure regardless of the shape of the structure. This makes it possible to, for example, assuredly insulate a structure inside of the semiconductor apparatus. Further, if an etching mask or the like is formed by this method, it becomes possible to assuredly protect a part that needs to be protected.

Then, as shown in FIG. 7(d), the resist film 12 is formed to cover the through hole. It is preferable that the resist film 12 be in the shape of a film. The thickness of the resist film 12 is not particularly limited. Materials of the resist film 12 are not particularly limited, and any publicly-known resist films may be employed. It is preferable to use photosensitive resin such as an epoxy group, for example. Further, an opening is formed in the resist film 12. The opening is formed within a part of the resist film 12, which part overlaps the bottom surface of the through hole in a direction vertical to the first surface of the semiconductor substrate 1. Methods of forming the opening are not particularly limited, but it is preferable that the opening be formed by photolithography.

As described above, in the method of producing a semiconductor apparatus in accordance with the present embodiment, the opening of the resist film 12 is formed within the part of the resist film 12, which part overlaps the bottom surface of the through hole. The “part of the resist film, which part overlaps the bottom surface of the through hole” indicates an area surrounded by contact points of the resist film 12 and perpendicular lines drawn from peripheries of the bottom surface of the through hole to the resist film 12. The opening is formed within this area.

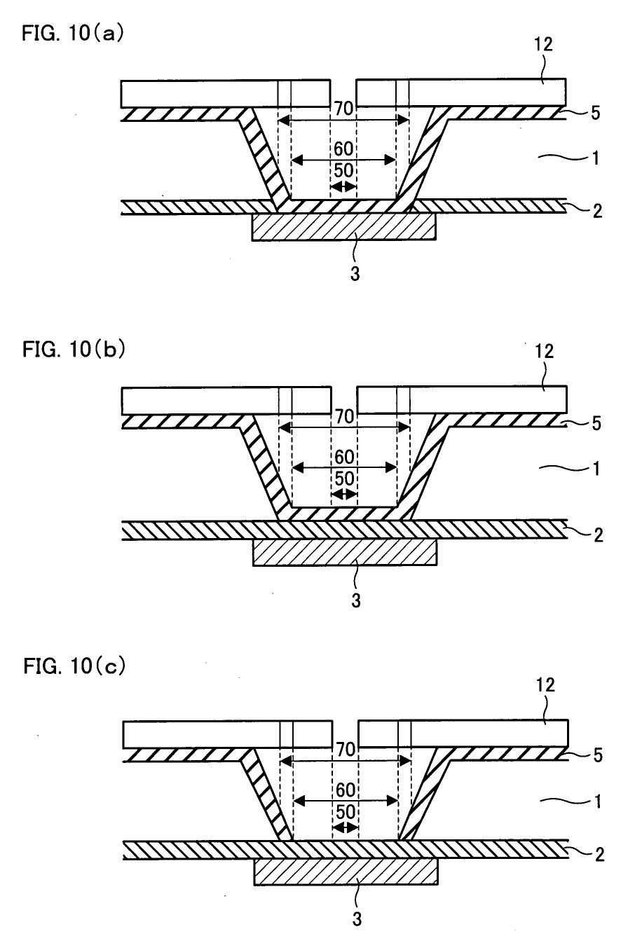

The following describes more specifically the opening in the resist film 12, with reference to FIG. 10(a). As shown in FIG. 10(a), in the method of producing a semiconductor apparatus in accordance with the present embodiment, the opening of the resist film 12 is formed within of the part of the resist film 12, which part overlaps the bottom surface of the through hole. In other words, the opening is formed within the area (part of the resist film 12, which part corresponds to an area indicated by an arrow 60) surrounded by contact points of the resist film 12 and the perpendicular lines drawn from peripheries of the bottom surface of the through hole to the resist film 12. Accordingly, the opening of the resist film 12 in accordance with the present embodiment includes an opening that corresponds to an area indicated by an arrow 50. In the case in which the resist film 12 has the opening corresponding to the area indicated by the arrow 50, if the second insulating film 5 is to be eliminated by anisotropic dry etching in a following step, a part of the second insulating film 5 is eliminated, which part overlaps the area indicated by the arrow 50. Thus, only the second insulating film 5 that overlaps the bottom surface of the through hole is eliminated without eliminating the second insulating film 5 formed on the side surface of the through hole. In a case in which the resist film 12 has an opening that corresponds to an area indicated by an arrow 70, the second insulating film 5 that overlaps the area indicated by the arrow 70 is eliminated. As a result, the second insulating film 5 formed on the side surface of the through hole is also eliminated. This causes the semiconductor substrate 1 to be revealed. Accordingly, the opening of the resist film 12, which opening corresponds to the area indicated by the arrow 70, is not included within the scope of the present invention.

Then, as shown in FIG. 7(e), anisotropic dry etching is carried out to eliminate a part of the second insulating film 5 that isolates the rear surface of the electrode pad 3 and the conductive wiring. The part of the second insulating film 5, which part is to be eliminated at this time, is within the bottom surface of the through hole. The size of the part to be eliminated is not particularly limited, as long as it is smaller than that of the bottom surface of the through hole. The shape of the part to be eliminated is not particularly limited. The second insulating film 5 is eliminated with the use of the resist film 12 so that only the second insulating film 5 formed on the rear surface of the electrode pad 3 is eliminated without etching the second insulating film 5 formed on the side surface of the through hole. Thereafter, a barrier metal layer (not illustrated) and a seed metal layer (not illustrated) for electrolytic plating are formed on the rear surface of the semiconductor substrate 1. Methods of forming the barrier metal layer and the seed metal layer are not particularly limited, and any publicly-known methods may be employed to form the barrier metal layer and the seed metal layer. For example, sputtering or CVD may be employed to form the barrier metal layer and the seed metal layer.

If the second insulating film 5 is a photosensitive resin film as discussed above, it is possible to replace the steps shown in FIGS. 7(d) and 7(e) with other steps. The following describes those other steps, with reference to FIG. 19(e). As shown in FIG. 19(e), an opening is formed in the second insulating film 5. The opening is within a part of the second insulating film 5, which part overlaps the bottom surface of the through hole, in the direction vertical to the first surface of the semiconductor substrate 1. Methods of forming the opening are not particularly limited, but it is preferable that the opening be formed by exposure and development of photolithography. The size of the opening to be formed at this time is not particularly limited, as long as it is smaller than the bottom surface of the through hole. The shape of the opening is not particularly limited.

When photolithography is employed to form the opening, a light shielding mask may be utilized to limit light illuminating the second insulating film formed on the bottom surface of the through hole. Specifically, a light shielding mask is utilized that only prevents light from illuminating a part of the second insulating film 5, at which part the opening is to be formed. For example the light shielding mask may be formed at the position of the opening formed in the resist film 12 shown in FIGS. 10(a) to 10(c).

Further, use of a photosensitive resin film as the second insulating film 5 makes it unnecessary to carry out etching on the second insulating film 5. It also becomes unnecessary to eliminate and open a part of the second insulating film 5 formed on the rear surface of the electrode pad 3.

Then, as shown in FIG. 7(f), the conductive wiring layer 6 is formed on the seed metal layer. The conductive wiring layer 6 functions as a rewiring pattern that electrically connects the rear surface of the electrode pad 3 and an external connection terminal that is to be formed later. The step shown in FIG. 19(f) is same as that shown in FIG. 7(f). Methods of forming the conductive wiring layer 6 are not particularly limited, and any publicly-known methods may be employed. For example, electrolytic copper plating may be employed to form the conductive wiring layer 6.

The following describes a concrete method of forming the conductive wiring layer 6. First, resist is applied to the rear surface of the semiconductor substrate 1. Then, the resist is exposed and developed by normal photolithography, thereby forming the rewiring pattern. If it is difficult to apply liquid-form resist to the semiconductor substrate 1 having the through hole, film-shaped resist may be used. Then, electrolytic copper plating is carried out, with the seed metal layer being a cathode. As a result, the thickness of a part of the rewiring pattern increases, which part corresponds to the opening section of the resist, and the conductive wiring layer 6 is formed. At this time, the thickness of the conductive wiring layer 6 is not particularly limited. It is preferable that the thickness be 10 μm to allow a solder ball to be mounted as an external input/output terminal in a following step, for example. Thereafter, the resist is eliminated, and etching is carried out to eliminate an unnecessary seed metal layer and an unnecessary barrier metal layer. It is possible to switch the order of the step of forming the rewiring pattern by photolithography and the step of electrolytic copper plating. Specifically, a conductive wiring layer is formed on the seed metal layer formed on the entire rear surface of the semiconductor substrate 1 by electrolytic copper plating or the like. Then, the resist is exposed and developed by normal photolithography so that the resist that constitutes the rewiring pattern remains, and at the same time, the resist that does not constitute the rewiring pattern is eliminated, thereby forming the rewiring pattern. Thereafter, etching is carried out to eliminate an unnecessary copper-plated layer, an unnecessary seed metal layer, and an unnecessary barrier metal layer.

Then, as shown in FIG. 7(g), photosensitive insulating resin is formed on the entire rear surface of the semiconductor substrate 1 to form the protection film 8. The step shown in FIG. 19(g) is same as that shown in FIG. 7(g). The photosensitive insulating resin is not particularly limited, and any publicly-known photosensitive insulating resin may be employed. Thereafter, a part of the protection film 8 is opened, at which part the external connection terminal is to be formed. Methods of forming this opening section are not particularly limited, and any publicly-known methods may be employed to form the opening section. For example, the opening section is formed by exposure and development of photolithography. Then, a solder ball, which becomes an external input terminal, is mounted on the opening section in the protection film 8, and dicing is carried out to form individual semiconductor chips, thereby completing production of the semiconductor apparatus of the present embodiment.

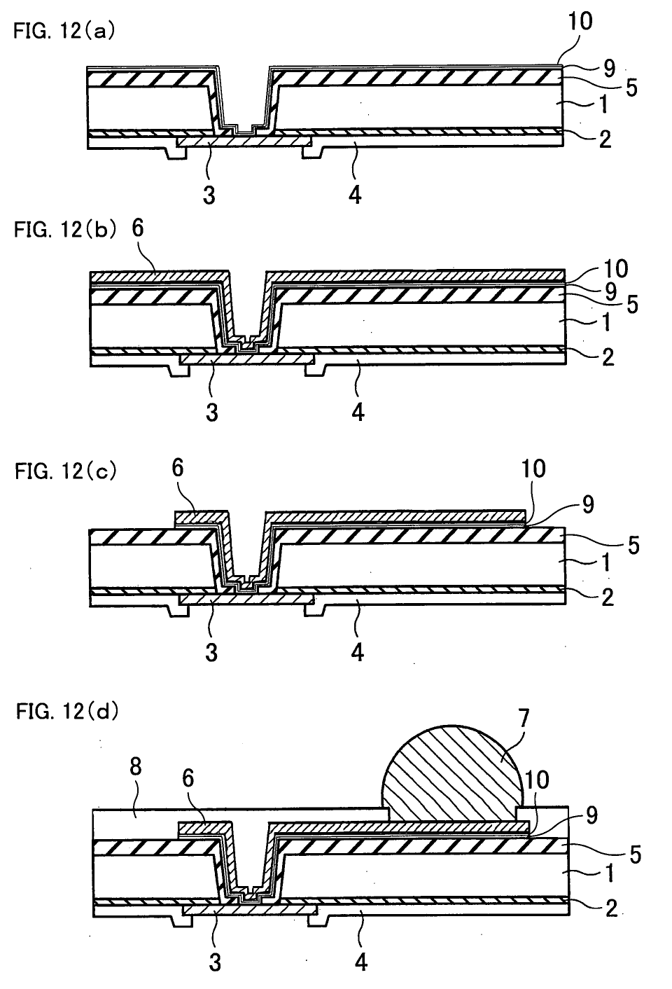

The barrier metal layer and the seed metal layer are not shown in FIGS. 7(e) to 7(g). FIGS. 12(a) to 12(d) show the barrier metal layer 9 and the seed metal layer 10 that are formed in the steps discussed above. As shown in FIGS. 12(a) to 12(d), a part of the second insulating film 5 is eliminated, and then the barrier metal layer 9 is formed on the rear surface of the semiconductor substrate 1. The seed metal layer 10 is formed on the barrier metal 9.

### Embodiment 2

The following describes a semiconductor apparatus of the present embodiment. Structures other than those described in the present embodiment are same as those of Embodiment 1. For convenience in description, components having the same functions as those of the components shown in the figures of Embodiment 1 are given the same reference numerals, and description thereof is omitted.

FIG. 2 is a cross section of a structure of the vicinity of an electrode section of a semiconductor apparatus of another embodiment of the present invention.

As shown in FIG. 2, in the semiconductor apparatus of the present embodiment, a through electrode is formed in an area where an electrode pad 3 is formed. Accordingly, in a semiconductor substrate 1, a through hole is formed immediately above the electrode pad 3. A second insulating film 5 is formed to cover a side surface of the through hole and a second surface of the semiconductor substrate 1. Further, a first insulating film 2 and the second insulating film 5 are formed so as to overlap a bottom surface of the through hole. It is preferable that the second insulating film 5 be a Si oxide film, an oxide film containing boron or phosphorus, a Si oxinitride film, a Si nitride film, or a laminated film of the foregoing films.

The first insulating film 2 and the second insulating film 5 are provided in such a way that at least a part of the first insulating film 2 and a part of the second insulating film 5 overlap, in a direction vertical to the first surface of the semiconductor substrate 1, the bottom surface of the through hole. A part of the first insulating film 2 and a part of the second insulating film 5 are opened. Specifically, an opening is formed in the first insulating film 2 and the second insulating film 5 in such a way as to avoid a periphery of the bottom surface of the through hole. The opening only needs to be formed in such a way as to avoid the periphery of the bottom surface of the through hole. The shape of the opening is not particularly limited.

In the semiconductor apparatus of the present embodiment, the conductive wiring layer 6, the protection film 8, the external input/output terminal 7, and the like are formed. They are same as in Embodiment 1. Therefore, description thereof is omitted.

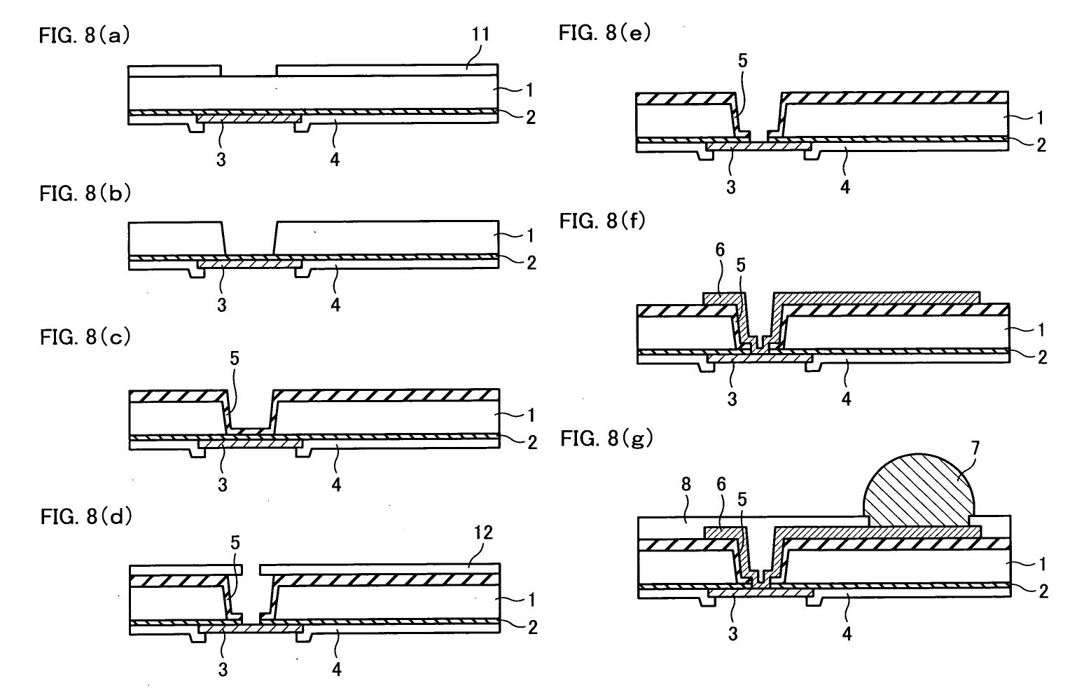

The following describes a method of producing a semiconductor apparatus in accordance with the present embodiment, with reference to FIGS. 8(a) to 8(g). The steps shown in FIGS. 8(a), 8(f), and 8(g) are same as those shown in FIGS. 7(a), 7(f), and 7(g) of Embodiment 1, respectively. Therefore, description of those steps is omitted.

In the method of producing a semiconductor apparatus in accordance with the present embodiment, the through hole is formed in the semiconductor substrate 1 by dry etching with the use of the resist film 11 as a mask as shown in FIG. 8(b). As a result of the dry etching, only the semiconductor substrate 1 is etched. In other words, the first insulating film 2 immediately above the electrode pad 3 remains. After the etching, the resist film 11 is peeled away.

Then, as shown in FIG. 8(c), the second insulating film 5 is formed on the side surface of the through hole, on the first insulating film 2 inside of the through hole, and on the second surface of the semiconductor substrate 1. Methods of forming the second insulating film are not particularly limited, but it is preferable that plasma CVD or the like be employed to form the second insulating film 5. It is preferable that the second insulating film 5 be a Si oxide film, an oxide film containing boron or phosphorus, a Si oxinitride film, a Si nitride film, or a laminated film of the foregoing films. When the second insulating film 5 is formed in the manner described above, the electrode pad 3 and the bottom surface of the through hole are isolated from each other immediately above the electrode pad 3 by an insulating film constituted of the first insulating film 2 and the second insulating film 5. This makes the through electrode further insulated.

Then, as shown in FIG. 8(d), the resist film 12 is formed to cover the through hole. It is preferable that the resist film 12 be in the shape of a film. The thickness of the resist film 12 is not particularly limited. Materials of the resist film 12 are not particularly limited, and any publicly-known resist films may be employed. It is preferable to use photosensitive resin such as an epoxy group, for example. An opening in the resist film 12 is formed within a part of the resist film 12, which part overlaps the bottom surface of the through hole in a direction vertical to the first surface of the semiconductor substrate 1. Methods of forming the opening are not particularly limited, but it is preferable that the opening be formed by photolithography. FIG. 10(b) shows in detail the opening in the resist film 12. In the present embodiment, the opening is formed within the area (part of the resist film 12, which part corresponds to an area indicated by an arrow 60) surrounded by contact points of the resist film 12 and the perpendicular lines drawn from peripheries of the bottom surface of the through hole to the resist film 12. Accordingly, the opening of the resist film 12 in accordance with the present embodiment includes an opening that corresponds to an area indicated by an arrow 50. In the case in which the resist film 12 has the opening corresponding to the area indicated by the arrow 50, if the first insulating film 2 and the second insulating film 5 are to be eliminated by anisotropic dry etching in a following step, a part of the first insulating film 2 and a part of the second insulating film 5, which parts overlap the area indicated by the arrow 50, are eliminated. Therefore, only the first insulating film 2 and the second insulating film 5 that overlap the bottom surface of the through hole are eliminated, without eliminating the second insulating film 5 formed on the side surface of the through hole. In a case in which the resist film 12 has an opening that corresponds to an area indicated by an arrow 70, the second insulating film 5 that overlaps the area indicated by the arrow 70 is eliminated. As a result, the second insulating film 5 formed on the side surface of the through hole is also eliminated. This causes the semiconductor substrate 1 to be revealed. Accordingly, the opening in the resist film 12, which opening corresponds to the area indicated by the arrow 70, is not included within the scope of the present invention.

Then, as shown in FIG. 8(e), anisotropic dry etching is carried out to eliminate a part of the first insulating film 2 and a part of the second insulating film 5, which films isolate the rear surface of the electrode pad 3 and the conductive wiring from each other. The part of the first insulating film 2 and the part of the second insulating film 5, which parts are to be eliminated at this time, are within the bottom surface of the through hole. The size of the part to be eliminated is not particularly limited, as long as it is smaller than that of the bottom surface of the through hole. The shape of the part to be eliminated is not particularly limited. The first insulating film 2 and the second insulating film 5 are eliminated with the use of the resist film 12 so that only the first insulating film 2 and the second insulating film 5 that are formed on the rear surface of the electrode pad 3 are eliminated, without etching the second insulating film 5 formed on the side surface of the through hole. Thereafter, a barrier metal layer (not illustrated) and a seed metal layer (not illustrated) for electrolytic plating are formed on the rear surface of the semiconductor substrate 1. Methods of forming the barrier metal layer and the seed metal layer are not particularly limited, and any publicly-known methods may be employed to form the barrier metal layer and the seed metal layer. For example, sputtering or CVD may be employed to form the barrier metal layer and the seed metal layer.

As described above, the steps following the foregoing step, that is, the steps shown in FIGS. 8(f) and 8(g) are same as those shown in FIGS. 7(f) and 7(g). Therefore, description thereof is omitted.

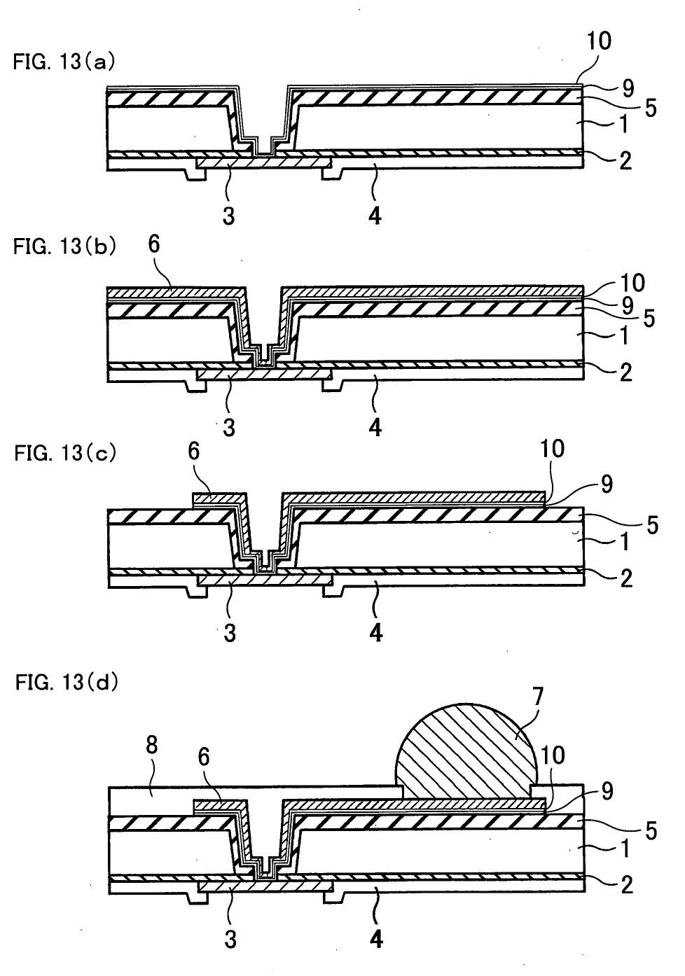

The barrier metal layer and the seed metal layer are not shown in FIGS. 8(e) to 8(g). FIGS. 13(a) to 13(d) show the barrier metal layer 9 and the seed metal layer 10 that are formed in the steps discussed above. As shown in FIGS. 13(a) to 13(d), a part of the second insulating film is eliminated, and then the barrier metal layer 9 is formed on the rear surface of the semiconductor substrate 1. The seed metal layer 10 is formed on the barrier metal layer 9.

### Embodiment 3

The following describes a semiconductor apparatus of the present embodiment. Structures other than those described in the present embodiment are same as those of Embodiment 1. For convenience in description, components having the same functions as those of the components shown in the figures of Embodiment 1 are given the same reference numerals, and description thereof is omitted.

FIG. 3 is a cross section of a structure of the vicinity of an electrode section of a semiconductor apparatus in accordance with another embodiment of the present invention.

As shown in FIG. 3, in the semiconductor apparatus of the present embodiment, a through electrode is formed in an area where an electrode pad 3 is formed. Accordingly, in a semiconductor substrate 1, a through hole is formed immediately above the electrode pad 3. The second insulating film 5 is formed to cover the side surface of the through hole and a second surface of the semiconductor substrate 1. The first insulating film 2 is formed so as to overlap the bottom surface of the through hole. It is preferable that the second insulating film 5 be made of an electrodeposition material. It is preferable that the electrodeposition material be polyimide, epoxy resin, acrylic resin, polyamine, or polycarboxylic acid resin. The second insulating film 5 made of an electrodeposition material allows the second insulating film 5 to be formed only on the second surface of the semiconductor substrate 1 and on the side surface of the through hole, without forming the second insulating film 5 on the first insulating film 2 formed on the bottom surface of the through hole.

The first insulating film 2 is formed in such a way that at least a part of the first insulating film 2 overlaps, in a direction vertical to a first surface of the semiconductor substrate 1, the bottom surface of the through hole. A part of the first insulating film 2 is opened. Specifically, in the first insulating film 2, an opening is formed in such a way as to avoid a periphery of the bottom surface of the through hole. The opening only needs to be formed in such a way as to avoid the periphery of the bottom surface of the through hole. The shape of the opening is not particularly limited.

In the semiconductor apparatus of the present embodiment, the conductive wiring layer 6, the protection film 8, the external input/output terminal 7, and the like are formed. They are same as in Embodiment 1, and therefore description thereof is omitted.

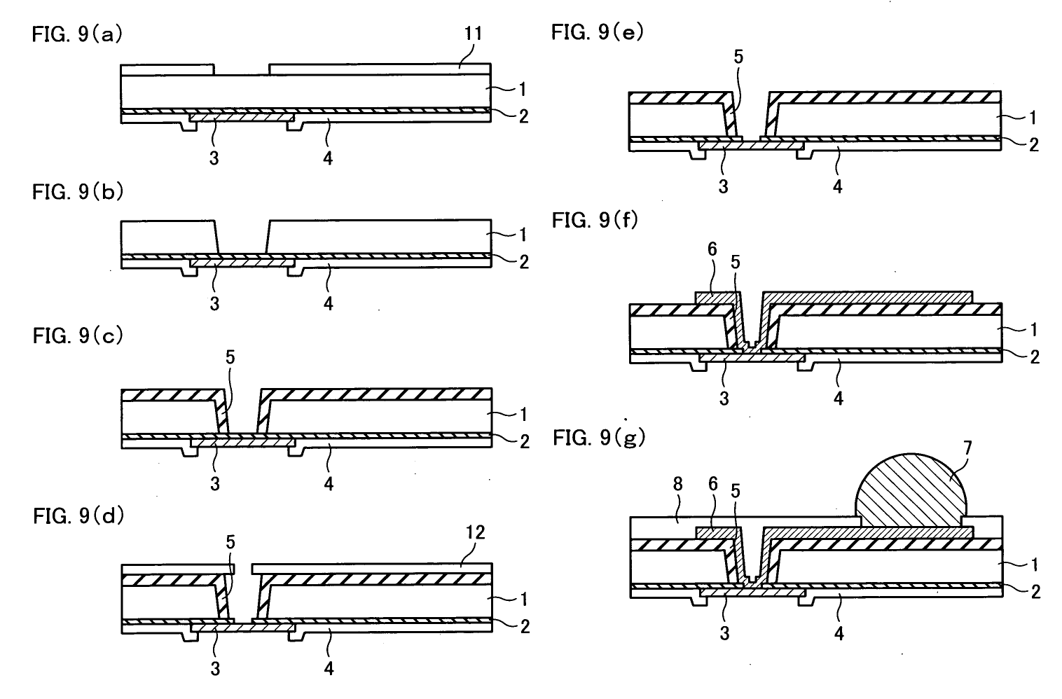

The following describes a method of producing a semiconductor apparatus in accordance with the present embodiment, with reference to FIGS. 9(a) to 9(g). The steps shown in FIGS. 9(a), 9(b), 9(f), and 9(g) are same as those shown in FIGS. 8(a), 8(b), 8(f), and 8(g) of Embodiment 2, respectively. Therefore, description of the steps is omitted.

As shown in FIG. 9(c), in the method in accordance with the present embodiment, the second insulating film 5 is formed on the side surface of the through hole and the second surface of the semiconductor substrate 1. It is preferable that the second insulating film 5 be made of an electrodeposition material. It is preferable that the electrodeposition material be polyimide, epoxy resin, acrylic resin, polyamine, or polycarboxylic acid resin. It is preferable that the second insulating film be formed by an electrodeposition-film forming method. The second insulating film 5 is formed in the manner described above. The first insulating film 2 remains on the bottom surface of the through hole. Therefore, no second insulating film 5 is formed on the bottom surface of the through hole. This results in that the electrode pad 3 and the bottom surface of the through hole are isolated from each other only by the first insulating film 2. In the case in which an electrodeposition material is used as the second insulating film 2, even if a notch is formed, the electrodeposition material covers the inside of the notch. This produces an advantage that, even when a conductive wiring layer is formed inside of the through hole, the conductive wiring layer and the semiconductor substrate are kept insulated.

Then, as shown in FIG. 9(d), the resist film 12 is formed to cover the through hole. It is preferable that the resist film 12 be in the shape of a film. The thickness of the resist film 12 is not particularly limited. Materials of the resist film 12 are not particularly limited, and any publicly-known resist films may be employed. It is preferable to use photosensitive resin such as an epoxy group, for example. An opening of the resist film 12 is formed within a part of the resist film 12, which part overlaps the bottom surface of the through hole in a direction vertical to the first surface of the semiconductor substrate 1. Methods of forming the opening are not particularly limited, but it is preferable that the opening be formed by use of photolithography. The opening formed in the resist film 12 is shown in detail in FIG. 10(c). The opening in the present embodiment is formed within the area (part of the resist film 12, which part corresponds to an area indicated by an arrow 60) surrounded by contact points of the resist film 12 and the perpendicular lines drawn from peripheries of the bottom surface of the through hole to the resist film 12. Accordingly, the opening of the resist film 12 in accordance with the present embodiment includes an opening that corresponds to an area indicated by an arrow 50. In the case in which the resist film 12 has the opening corresponding to the area indicated by the arrow 50, if the first insulating film 2 is to be eliminated by anisotropic dry etching in a following step, a part of the first insulating film 2, which part overlaps the area indicated by the arrow 50, is eliminated. Therefore, only the first insulating film 2 that overlaps the bottom surface of the through hole is eliminated, without eliminating the second insulating film 5 formed on the side surface of the through hole. In a case in which the resist film 12 has an opening that corresponds to an area indicated by an arrow 70, the second insulating film 5 that overlaps the area indicated by the arrow 70 is eliminated. As a result, the second insulating film 5 formed on the side surface of the through hole is also eliminated. This causes the semiconductor substrate 1 to be revealed. Accordingly, the opening of the resist film 12, which opening corresponds to the area indicated by the arrow 70, is not included within the scope of the present invention.

Then, as shown in FIG. 9(e), anisotropic dry etching is carried out to eliminate a part of the first insulating film 2, which part isolates the rear surface of the electrode pad 3 and the conductive wiring. A part of the first insulating film 2, which part is to be eliminated at this time, is inside of the bottom surface of the through hole. The size of the part to be eliminated is not particularly limited, as long as it is smaller than that of the bottom surface of the through hole. The shape of the part to be eliminated is not particularly limited. The first insulating film 2 is eliminated with the use of the resist film 12 so that only the first insulating film 2 formed on the rear surface of the electrode pad 3 is eliminated without etching the second insulating film 5 formed on the side surface of the through hole. Thereafter, a barrier metal layer (not illustrated) and a seed metal layer (not illustrated) for electrolytic plating are formed on the rear surface of the semiconductor substrate 1. Methods of forming the barrier metal layer and the seed metal layer are not particularly limited, and any publicly-known methods may be employed to form the barrier metal layer and the seed metal layer. For example, sputtering or CVD may be employed to form the barrier metal layer and the seed metal layer.

As described above, the steps following the foregoing step, that is, the steps shown in FIGS. 9(f) and 9(g) are same as those shown in FIGS. 8(f) and 8(g). Therefore, description thereof is omitted.

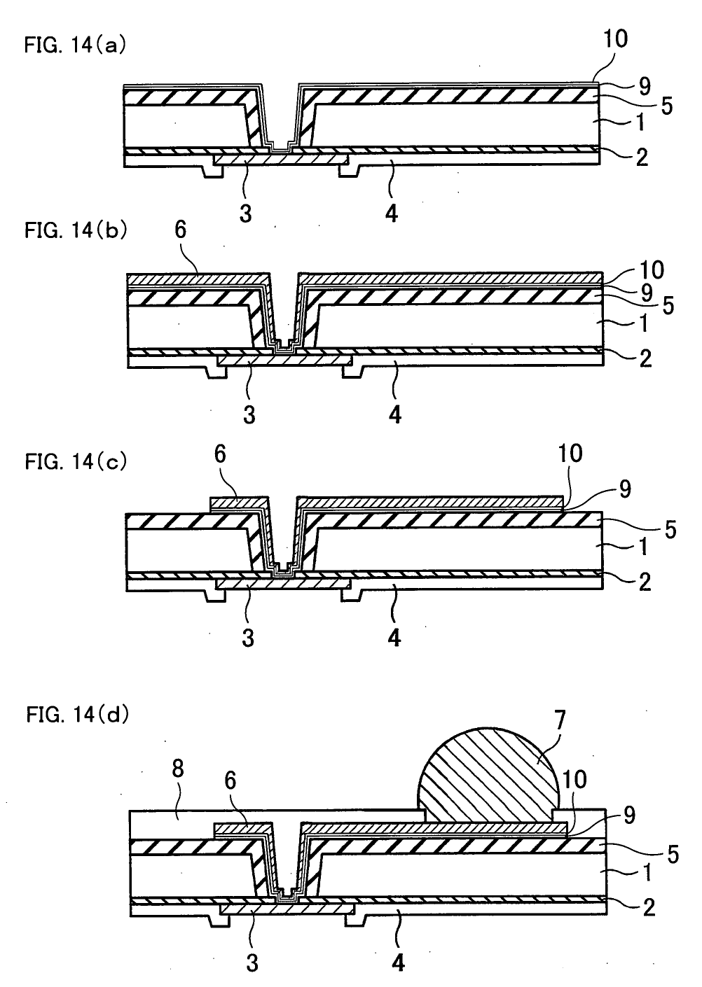

The barrier metal layer and the seed metal layer are not shown in FIGS. 9(e) to 9(g). FIGS. 14(a) to 14(d) show the barrier metal layer 9 and the seed metal layer 10 that are formed in the steps discussed above. As shown in FIGS. 14(a) to 14(d), a part of the second insulating film 5 is eliminated, and then the barrier metal layer 9 is formed on the rear surface of the semiconductor substrate 1. The seed metal layer 10 is formed on the barrier metal layer 9.

### Embodiment 4

The following describes a semiconductor apparatus of the present embodiment. Structures other than those described in the present embodiment are same as those of Embodiment 1. For convenience in description, components having the same functions as those of the components shown in the figures of Embodiment 1 are given the same reference numerals, and description thereof is omitted.

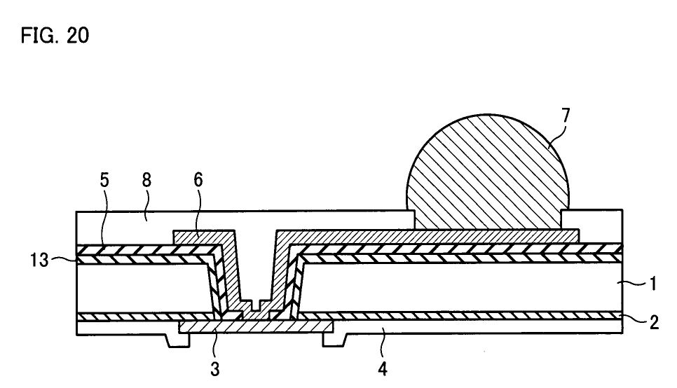

FIG. 20 is a cross section of a structure of the vicinity of an electrode section of a semiconductor apparatus in accordance with another embodiment of the present invention.

As shown in FIG. 20, in the semiconductor apparatus of the present embodiment, a through electrode is formed in an area where an electrode pad 3 is formed. Accordingly, a through hole is formed immediately above an electrode pad 3 in a semiconductor substrate 1. The second insulating film 5 is formed to cover the side surface of the through hole and the second surface of the semiconductor substrate 1. Further, the third insulating film 13 is formed so as to overlap the bottom surface of the through hole. It is preferable that the third insulating film 13 be a Si oxide film, an oxide film containing boron or phosphorus, a Si oxinitride film, a Si nitride film, or a laminated film of the foregoing films. It is preferable that the second insulating film 5 be a photosensitive resin film and be a film made of polyimide, epoxy resin, acrylic resin, or silicone resin.

The first insulating film 2 and the second insulating film 5 that are formed in such a way that at least a part of the first insulating film 2 and a part of the second insulating film 5 overlap, in a direction vertical to a first surface of the semiconductor substrate 1, the bottom surface of the through hole. A part of the first insulating film 2 and a part of the second insulating film 5 are opened. Specifically, an opening is formed in the first insulating film 2 and the second insulating film 5 in such a way as to avoid a periphery of the bottom surface of the through hole. The opening only needs to be formed in such a way as to avoid the periphery of the bottom surface of the through hole. The shape of the opening is not particularly limited.

In the semiconductor apparatus of the present embodiment, the conductive wiring layer 6, the protection film 8, the external input/output terminal 7, and the like are formed. They are same as those of Embodiment 1, and therefore description thereof is omitted.

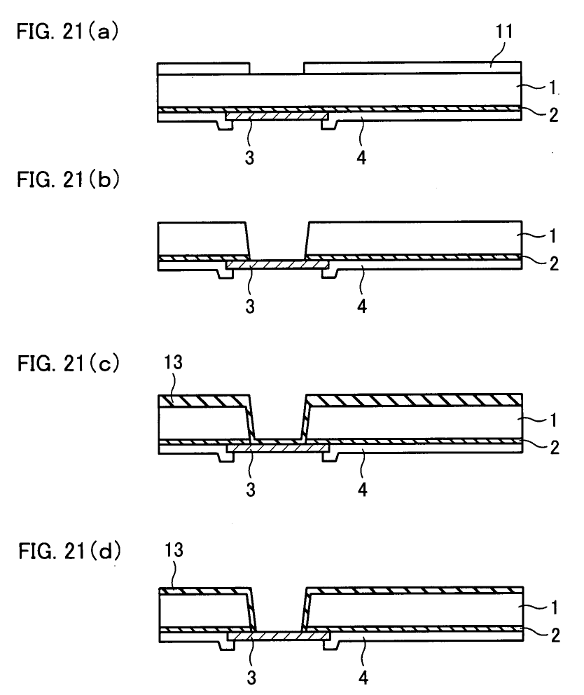

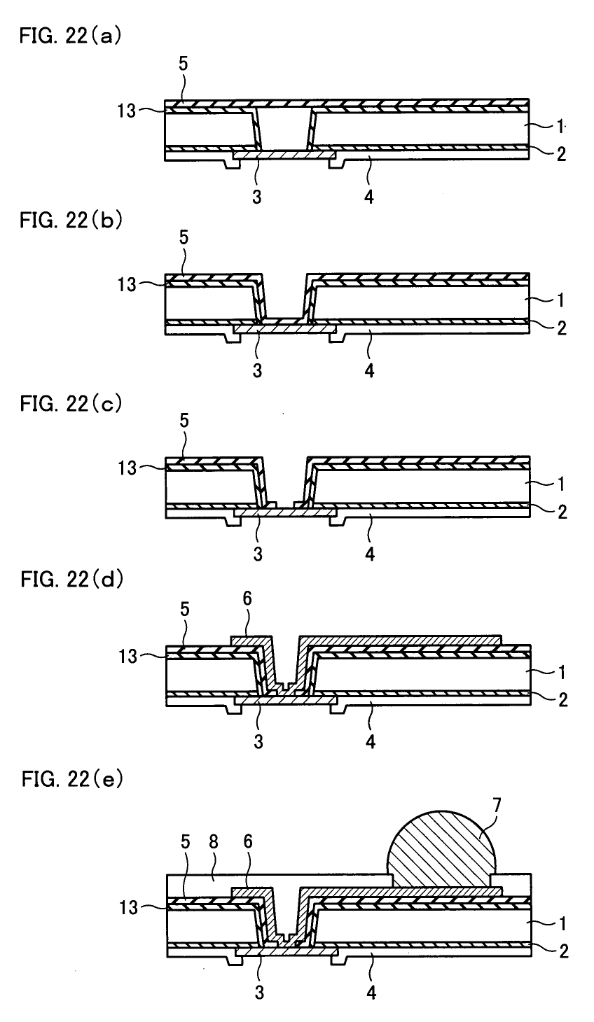

The following describes a method of producing a semiconductor apparatus in accordance with the present embodiment, with reference to FIGS. 21(a) to 21(d) and FIGS. 22(a) to 22(e). The steps shown in FIGS. 21(a) and 21(b) are same as those shown in FIGS. 7(a) and 7(b) of Embodiment 1, respectively. Therefore, description of the steps is omitted.

In the method of the present embodiment, a third insulating film 13 is formed on a through hole shown in FIG. 21(b). Specifically, as shown in FIG. 21(c), the third insulating film 13 is formed on a side surface of the through hole, a bottom surface of the through hole, and a second surface of the semiconductor substrate 1. Methods of forming the third insulating film 13 are not particularly limited, but it is preferable that plasma CVD or the like be employed to form the third insulating film 13. It is preferable that the third insulating film 13 be a Si oxide film, an oxide film containing boron or phosphorus, a Si oxinitride film, a Si nitride film, or a laminated film of the foregoing films.

Then, as shown in FIG. 21(d), anisotropic etching is carried out, with the use of ions such as Ar and Xe, on the third insulating film 13 formed on the second surface of the semiconductor substrate 1, the inner wall of the through hole, and the bottom surface of the through hole. As a result, only the third insulating film 13 formed so as to overlap the bottom surface of the through hole is eliminated without eliminating the third insulating film 13 formed on the inner side surface of the through hole.

Then, as shown in FIG. 22(a), a second insulating film 5 is formed to cover the through hole. The second insulating film 5 is adhered to the second surface of the semiconductor substrate 1 to cover the through hole. The second insulating film 5 is not particularly limited, but it is preferable that the second insulating film 5 be a photosensitive resin film. It is preferable that the photosensitive resin film be a film made of polyimide, epoxy resin, acrylic resin, or silicone resin.

Then, as shown in FIG. 22(b), the second insulating film 5 in the shape of a sheet is adhered to the second surface of the semiconductor substrate 1 under reduced pressure, and thereafter pressure is applied. Due to the difference in pressure between the outside (pressure applied) and the inside (pressure reduced) of the through hole, and the second insulating film 5 in the shape of a sheet is adhered to the second surface of the semiconductor substrate 1 and to an inner wall of the through hole. In this case, it is preferable to apply heat to the second insulating film 5 and to the semiconductor substrate 1 so that it becomes easy to change the shapes of the second insulating film 5 and the semiconductor substrate 1. The shape of the second insulating film 5 is not particularly limited, but a sheet-shape is preferable. The thickness of the second insulating film 5 is not particularly limited.

Then, as shown in FIG. 22(c), an opening is formed in the second insulating film 5. The opening is formed within a part of the second insulating film 5, which part overlaps the bottom surface of the through hole in a direction vertical to the first surface of the semiconductor substrate 1. Methods of forming the opening are not particularly limited, but it is preferable that the opening be formed by exposure and development of photolithography. The size of the opening to be formed at this time is not particularly limited, as long as it is smaller than the bottom surface of the through hole. The shape of the opening is not particularly limited. Accordingly, use of the combination of the second insulating film 5 and the third insulating film 13 makes the through electrode further insulated.

Thereafter, as shown in FIGS. 22(d) and 22(e), a seed metal layer (not illustrated) for electrolytic plating and a barrier metal layer (not illustrated) are formed on the rear surface of the semiconductor substrate 1. Methods of forming the barrier metal layer and the seed metal layer are not particularly limited, and any publicly-known methods may be employed to form the barrier metal layer and the seed metal layer. For example sputtering or CVD may be employed to form the barrier metal layer and the seed metal layer.

As described above, the foregoing steps, i.e. steps shown in FIGS. 22(d) and 22(e), are same as those shown in FIGS. 7(f) and 7(g). Therefore, description of the steps is omitted.

### Embodiment 5

The following describes a semiconductor apparatus of the present embodiment. Structures other than those described in the present embodiment are same as those of Embodiment 1. For convenience in description, components having the same functions as those of the components shown in the figures of Embodiment 1 are given the same reference numerals, and description thereof is omitted.

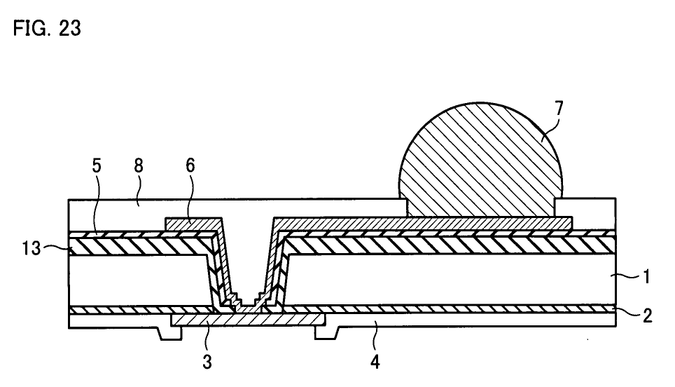

FIG. 23 is a cross section of a structure of the vicinity of an electrode section of a semiconductor apparatus in accordance with an embodiment of the present invention.

As shown in FIG. 23, a through electrode is formed in an area where an electrode pad 3 also in the semiconductor apparatus of the present embodiment. Accordingly, a through hole is formed immediately above the electrode pad 3 in a semiconductor substrate 1. A third insulating film 13 and a second insulating film 5 are formed to cover a side surface of the through hole and a second surface of the semiconductor substrate 1. Further, the third insulating film 13 and the second insulating film 5 are formed so as to overlap a bottom surface of the through hole. It is preferable that the third insulating film 13 be a Si oxide film, an oxide film containing boron or phosphorus, a Si oxinitride film, a Si nitride film, a laminated film of the foregoing films, or a film made of an electrodeposition material. It is preferable that the second insulating film 5 be formed of a photosensitive resin film and be a film made of polyimide, epoxy resin, acrylic resin, or silicone resin. It is preferable that the electrodeposition material be polyimide, epoxy resin, acrylic resin, polyamine, or polycarboxylic acid resin. A laminate film of the third insulating film 13 and the second insulating film 5 is formed so as to that insulation of the through electrode further improves.

The third insulating film 13 is provided in such a way that at least a part of the third insulating film 13 overlaps, in a direction vertical to a first surface of the semiconductor substrate 1, a bottom surface of the through hole. A part of the third insulating film 13 is opened. Specifically, this opening in the third insulating film 13 is formed in such a way as to avoid a periphery of the bottom surface of the through hole. The opening only needs to be formed in such a way as to avoid the periphery of the bottom surface of the through hole. The shape of the opening is not particularly limited.

In the semiconductor apparatus of the present embodiment, the conductive wiring layer 6, the protection film 8, the external input/output terminal 7, and the like are formed. They are same as in Embodiment 1. Therefore, description thereof is omitted.

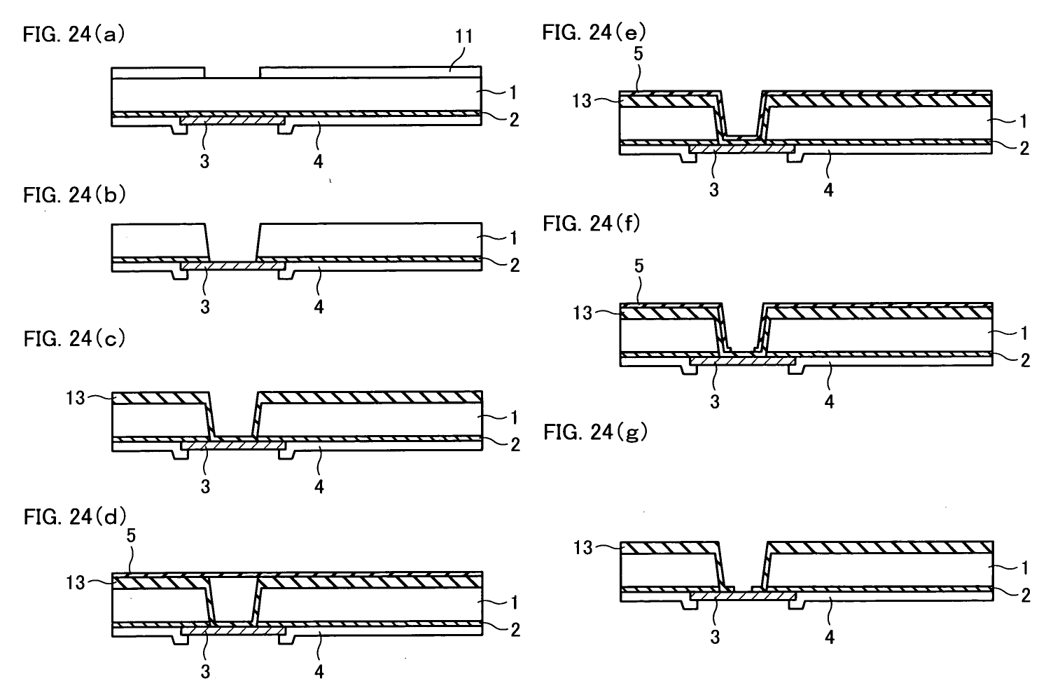

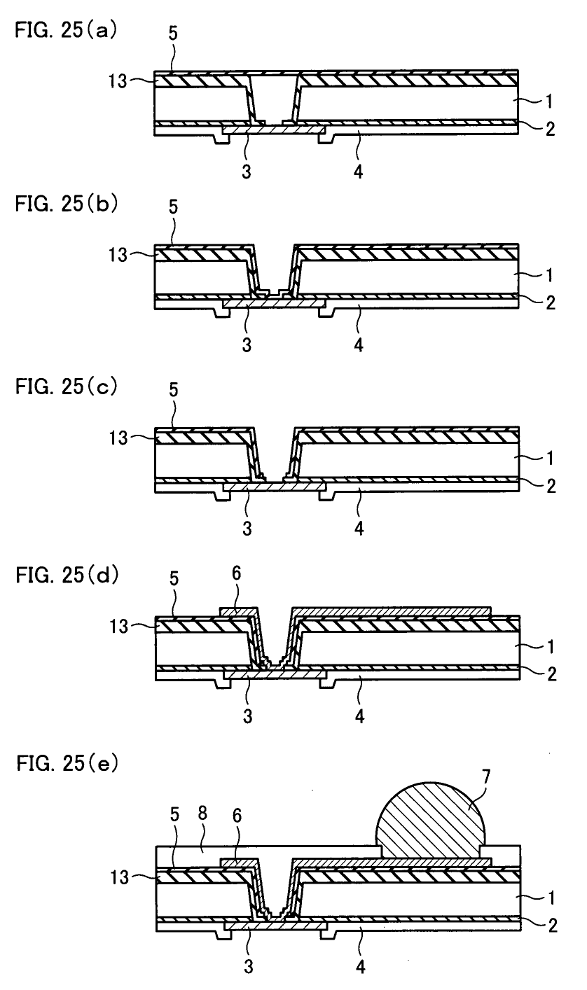

The following describes a method of producing a semiconductor apparatus in accordance with the present embodiment, with reference to FIGS. 24(a) to 24(g) and FIGS. 25(a) to 25(e). The steps shown in FIGS. 24(a), 24(b), and 24(c) are same as those shown in FIGS. 21(a), 21(b), and 21(c), respectively. Further, the steps shown in FIGS. 25(a), 25(b), 25(c), 25(d), and 25(e) are same as those shown in FIGS. 22(a), 22(b), 22(c), 22(d), and 22(e), respectively. Therefore, description of the steps is omitted.

In the method in accordance with the present embodiment, the third insulating film 13 is formed on the side surface of the through hole and the second surface of the semiconductor substrate 1, as shown in FIG. 24(c). It is preferable that the third insulating film 13 be a Si oxide film, an oxide film containing boron or phosphorus, a Si oxinitride film, a Si nitride film, a laminated film of the foregoing films, or a film made of an electrodeposition material. It is preferable that the electrodeposition material be polyimide, epoxy resin, acrylic resin, polyamine, or polycarboxylic acid resin. It is preferable that the film made of an electrodeposition material be formed by an electrodeposition-film forming method. The third insulating film 13 is formed in the manner described above. Therefore, the third insulating film 13 is formed on the bottom surface of the through hole. This results in that the electrode pad 3 and the bottom surface of the through hole are isolated from each other only by the third insulating film 13. In the case in which an electrodeposition material is employed as the third insulating film 13, even if a notch is formed, the electrodeposition material covers the inside of the notch. This produces an advantage that, even if a conductive wiring layer is formed in the through hole, the conductive wiring layer and the semiconductor substrate are kept insulated.

Then, as shown in FIG. 24(d), the second insulating film 5 is formed to cover the through hole. The second insulating film 5 is adhered to the second surface of the semiconductor substrate 1 to cover the through hole. The second insulating film 5 is not particularly limited, but is preferable that the second insulating film 5 be a photosensitive resin film. It is preferable that the photosensitive resin film be a film made of polyimide, epoxy resin, acrylic resin, or silicone resin.

Then, as shown in FIG. 24(e), the second insulating film 5 in the shape of a sheet is adhered to the second surface of the semiconductor substrate 1 under reduced pressure, and thereafter pressure is applied. Due to the difference in pressure between the outside (pressure applied) and the inside (pressure reduced) of the through hole, the second insulating film 5 in the shape of a sheet is adhered to the second surface of the semiconductor substrate 1 and the inner wall of the through hole. In this case, it is preferable to apply heat to the second insulating film 5 and to the semiconductor substrate 1 so that it becomes easy to change the shapes of the second insulating film 5 and the semiconductor substrate 1. The shape of the second insulating film 5 is not particularly limited, but a sheet-shape is preferable. The thickness of the second insulating film 5 is not particularly limited.

Then, as shown in FIG. 24(f), an opening is formed in the second insulating film 5. The opening is formed within a part of the second insulating film 5, which part overlaps the bottom surface of the through hole in a direction vertical to the first surface of the semiconductor substrate 1. The second insulating film 5 functions as an etching mask. Methods of forming the opening are not particularly limited, but it is preferable that the opening be formed by exposure and development of photolithography. The size of the opening formed at this time is not particularly limited, as long as it is smaller than the bottom surface of the through hole. The shape of the opening is not particularly limited.

Then, as shown in FIG. 24(g), anisotropic dry etching is carried out with the use of the etching mask. As a result, the third insulating film 13 formed so as to overlap the bottom surface of the through hole is eliminated, thereby forming a connection opening to the electrode pad 3 in such a way as to avoid the periphery of the bottom surface of the through hole. It is preferable that the etching mask be peeled away by a publicly-known method.

Then, as shown in FIGS. 25(a), 25(b), and 25(c), the second insulating film 5 is formed by the steps same as those shown in FIGS. 24(d), 24(e), and 24(f). Accordingly, use of the combination of the second insulating film 5 and the third insulating film 13 further improves insulation of the through electrode.

Thereafter, as shown in FIGS. 25(d) and 25(e), a seed metal layer (not illustrated) for electrolytic plating and a barrier metal layer (not illustrated) are formed on the rear surface of the semiconductor substrate 1. Methods of forming the barrier metal layer and the seed metal layer are not particularly limited, and any publicly-known methods may be employed to form the barrier metal layer and the seed metal layer. For example sputtering or CVD may be employed to form the barrier metal layer and the seed metal layer.

As described above, the foregoing steps, i.e. steps shown in FIGS. 25(d) and 25(e), are same as those shown in FIGS. 7(f) and 7(g). Therefore, description of the steps is omitted.

### Embodiment 6

The following describes a semiconductor apparatus of the present embodiment. Structures other than those described in the present embodiment are same as those of Embodiment 1. For convenience in description, components having the same functions as those of the components shown in the figures of Embodiment 1 are given the same reference numerals, and description thereof is omitted.

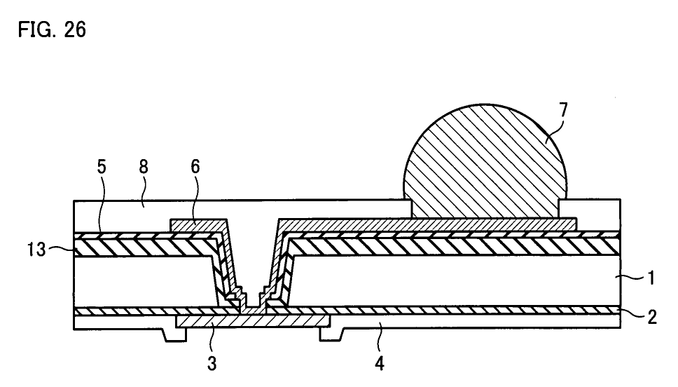

FIG. 26 is a cross section of a structure of the vicinity of an electrode section of a semiconductor apparatus in accordance with another embodiment of the present invention.

As shown in FIG. 26, in the semiconductor apparatus of the present embodiment, a through electrode is formed in an area where an electrode pad 3 is formed. Accordingly, a through hole is formed immediately above an electrode pad 3 in a semiconductor substrate 1. The third insulating film 13 and the second insulating film 5 are formed to cover the side surface of the through hole and the second surface of the semiconductor substrate 1. Further, the third insulating film 13, the second insulating film 5, and the first insulating film 2 are formed in such a way as to overlap the bottom surface of the through hole. It is preferable that the third insulating film 13 be a Si oxide film, an oxide film containing boron or phosphorus, a Si oxinitride film, a Si nitride film, or a laminated film of the foregoing films. It is preferable that the second insulating film 5 be a photosensitive resin film. It is preferable that the photosensitive resin film be a film made of polyimide, epoxy resin, acrylic resin, or silicone resin. It is preferable that the first insulating film 2 be a Si oxide film, an oxide film containing boron or phosphorus, a Si oxinitride film, a Si nitride film, or a laminated film of the foregoing films. The first insulating film 2 and a laminate film of the third insulating film 13 and the second insulating film 5 are formed so that insulation of the through electrode further improves.

A third insulating film 13, a second insulating film 5, and a first insulating film 2 are provided in such a way that at least a part of the third insulating film 13, a part of the second insulating film 5, and a part of the first insulating film 2 overlap a bottom surface of a through hole in a direction vertical to a first surface of the semiconductor substrate 1. A part of the third insulating film 13, a part of the second insulating film 5, and a part of the first insulating film 2 are opened. Specifically, an opening is formed inside in such a way as to avoid a periphery of a bottom surface of a through hole. The opening only needs to be formed in such a way as to avoid the periphery of the bottom surface of the through hole. The shape of the opening is not particularly limited.

In the semiconductor apparatus of the present embodiment, the conductive wiring layer 6, the protection film 8, the external input/output terminal 7, and the like are formed. They are same as in Embodiment 1. Therefore, description thereof is omitted.

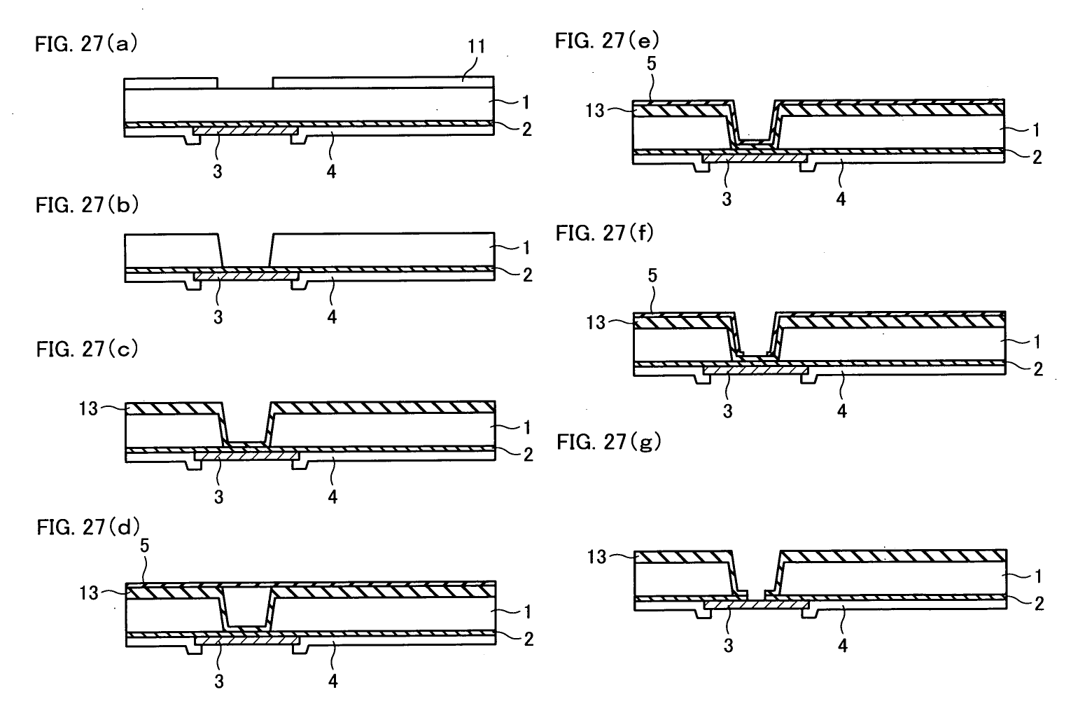

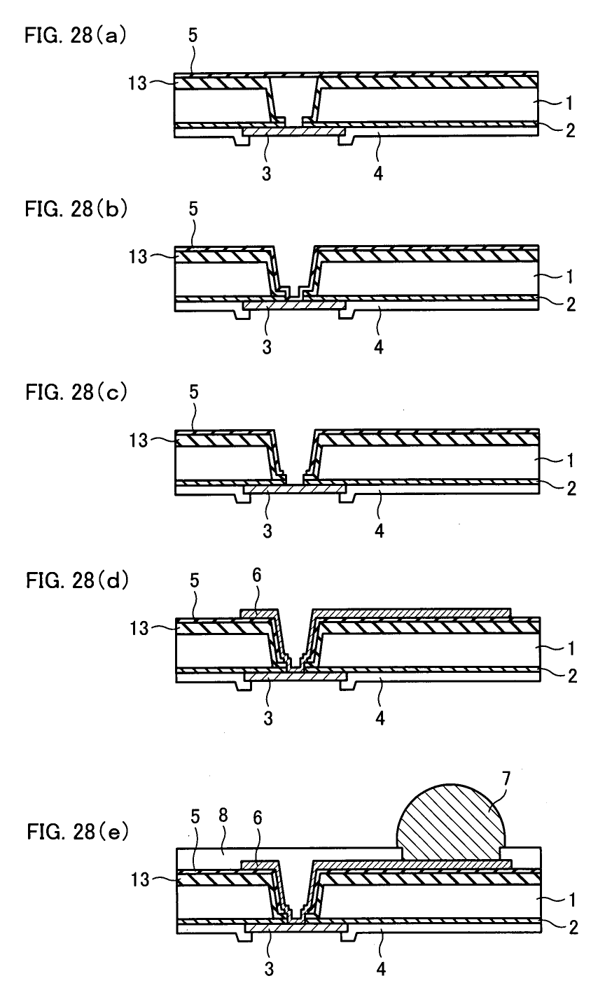

The following describes a method of producing a semiconductor apparatus in accordance with the present embodiment, with reference to FIGS. 27(a) to 27(g) and FIGS. 28(a) to 28(e). The steps shown in FIGS. 27(a) and 27(b) are same as those shown in FIGS. 24(a) and 24(b). Further, the steps shown in FIGS. 28(a), 28(b), 28(c), 28(d), and 28(e) are same as those shown in FIGS. 25(a), 25(b), 25(c), 25(d), and 25(e). Therefore, description of the steps is omitted.

As shown in FIG. 27(b), in the method in accordance with the present embodiment, dry etching is carried out on the semiconductor substrate 1 with the use of the resist film 11 as a mask, thereby forming the through hole. The semiconductor substrate 1 is etched by dry etching. As a result, the first insulating film 2 on the rear surface of the electrode pad 3 is revealed. After the etching, the resist film 11 is peeled away.

As shown in FIG. 27(c), the third insulating film 13 is formed on the side surface of the through hole and the second surface of the semiconductor substrate 1. It is preferable that the third insulating film 13 be a Si oxide film, an oxide film containing boron or phosphorus, a Si oxinitride film, a Si nitride film, a laminated film of the foregoing films. It is preferable that the first insulating film 2 be a Si oxide film, an oxide film containing boron or phosphorus, a Si oxinitride film, a Si nitride film, or a laminated film of the foregoing films. A laminate film of the third insulating film 13 and the first insulating film 2 is formed on the bottom surface of the through hole in the manner described above.

Then, as shown in FIG. 27(d), the second insulating film 5 is formed to cover the through hole. The second insulating film 5 is adhered to the second surface of the semiconductor substrate 1 to cover the through hole. The second insulating film 5 is not particularly limited, but it is preferable that the second insulating film 5 be a photosensitive resin film. It is preferable that the photosensitive resin film be a film made of polyimide, epoxy resin, acrylic resin, or silicone resin.

Then, as shown in FIG. 27(e), a photosensitive resin film in the shape of a sheet is adhered to the second surface of the semiconductor substrate 1 under reduced pressure, and thereafter pressure is applied. Due to the difference in pressure between the outside (pressure applied) and the inside (pressure reduced) of the through hole, the second insulating film 5 in the shape of a sheet is adhered to the second surface of the semiconductor substrate 1 and to the inner wall of the through hole. At this time, it is preferable that heat be applied to the second insulating film 5 and to the semiconductor substrate 1 so that it becomes easy to change the shapes of the second insulating film 5 and the semiconductor substrate 1. The shape of the second insulating film 5 is not particularly limited, but a sheet-shape is preferable. The thickness of the second insulating film 5 is not particularly limited.

Then, as shown in FIG. 27(f), an opening is formed in the second insulating film 5. The opening is formed within a part of the second insulating film 5, which part overlaps the bottom surface of the through hole in a direction vertical to the first surface of the semiconductor substrate 1. The second insulating film 5 functions as an etching mask. Methods of forming the opening are not particularly limited, but it is preferable that the opening be made by exposure and development of photolithography. The size of the opening formed at this time is not particularly limited, as long as it is smaller than the bottom surface of the through hole. The shape of the opening is not particularly limited.

Then, as shown in FIG. 27(g), anisotropic dry etching is carried out with the use of the etching mask. As a result, the third insulating film 13 and the first insulating film 2 that are formed so as to overlap the bottom surface of the through hole are eliminated, thereby forming a connection opening to the electrode pad 3 in such a way as to avoid the periphery of the bottom surface of the through hole. Thereafter, it is preferable that the etching mask be peeled away and eliminated by a publicly-known method.

Then, as shown in FIGS. 28(a), 28(b), and 28(c), the second insulating film 5 is formed by the steps same as those shown in FIGS. 27(d), 27(e), and 27(f). Accordingly, use of the combination of the second insulating film 5 and the third insulating film 13 further improves insulation of the through electrode.

Thereafter, as shown in FIGS. 28(d) and 28(e), a seed metal layer (not illustrated) for electrolytic plating and a barrier metal layer (not illustrated) are formed on the rear surface of the semiconductor substrate 1. Methods of forming the barrier metal layer and the seed metal layer are not particularly limited, and any publicly-known methods may be employed to form the barrier metal layer and the seed metal layer. For example sputtering or CVD may be employed to form the barrier metal layer and the seed metal layer.

As described above, the foregoing steps, i.e. the steps shown in FIGS. 28(d) and 28(e), are same as those shown in FIGS. 7(f) and 7(g). Therefore, description of the steps is omitted.

### Embodiment 7

The following describes a semiconductor apparatus of the present embodiment. Structures other than those described in the present embodiment are same as those of Embodiment 1. For convenience in description, components having the same functions as those of the components shown in the figures of Embodiment 1 are given the same reference numerals, and description thereof is omitted.

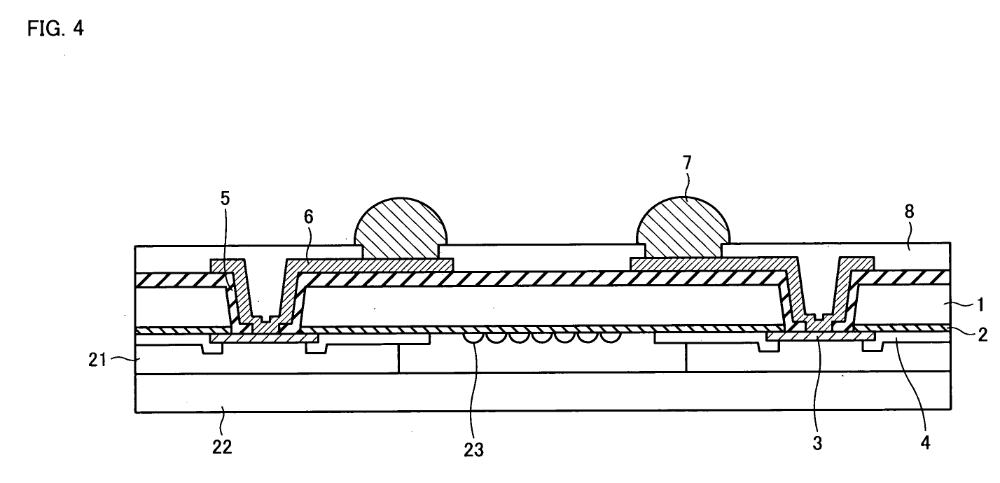

FIGS. 4 to 6 and FIGS. 29 to 31 show an exemplary structure of a CCD (Charge Coupled Device) package employing a semiconductor apparatus of the present invention. The CCD packages shown in FIGS. 4, 5, 6, 29, 30, and 31 are same in structure of the vicinity of the through hole as the semiconductor apparatuses described in Embodiments 1, 2, 3, 4, 5, and 6, respectively.

In the CCD packages shown in FIGS. 4 to 6 and FIGS. 29 to 31, a through hole is formed immediately above an electrode pad 3 formed on a first surface of the semiconductor substrate 1. The electrode pad 3 formed on the first surface of the semiconductor substrate 1 is electrically connected, via a conductive wiring layer 6, to an external input/output terminal 7 formed on a second surface of the semiconductor substrate 1. The conductive wiring layer 6 is not particularly limited, and any publicly-known conductive wirings may be employed. For example the conductive wiring layer 6 may be formed of copper plate. At this time, the electrode pad 3 and the conductive wiring layer 6 are electrically insulated from the semiconductor substrate 1. In other words, the first insulating film 2 and the second insulating film 5 keep this insulation. As the details of the foregoing structure are already discussed in Embodiments 1 to 6, description thereof is omitted here.

In the CCD package of the present embodiment, a reinforcing plate 22 is bonded to the first surface of the semiconductor substrate 1 via a bonding layer 21. A CCD light receiving section 23 (pixel area) is provided in between the semiconductor substrate 1 and the reinforcing plate 22. The bonding layer 21 is formed so as to avoid the area where the CCD light receiving section 23 is formed. Materials of the bonding layer 21 are not particularly limited, and any publicly-known bonding agents may be employed. It is preferable that the reinforcing plate 22 be a light transmitting material. For example glass, plastic, or acrylic resin may be employed as the light transmitting material.

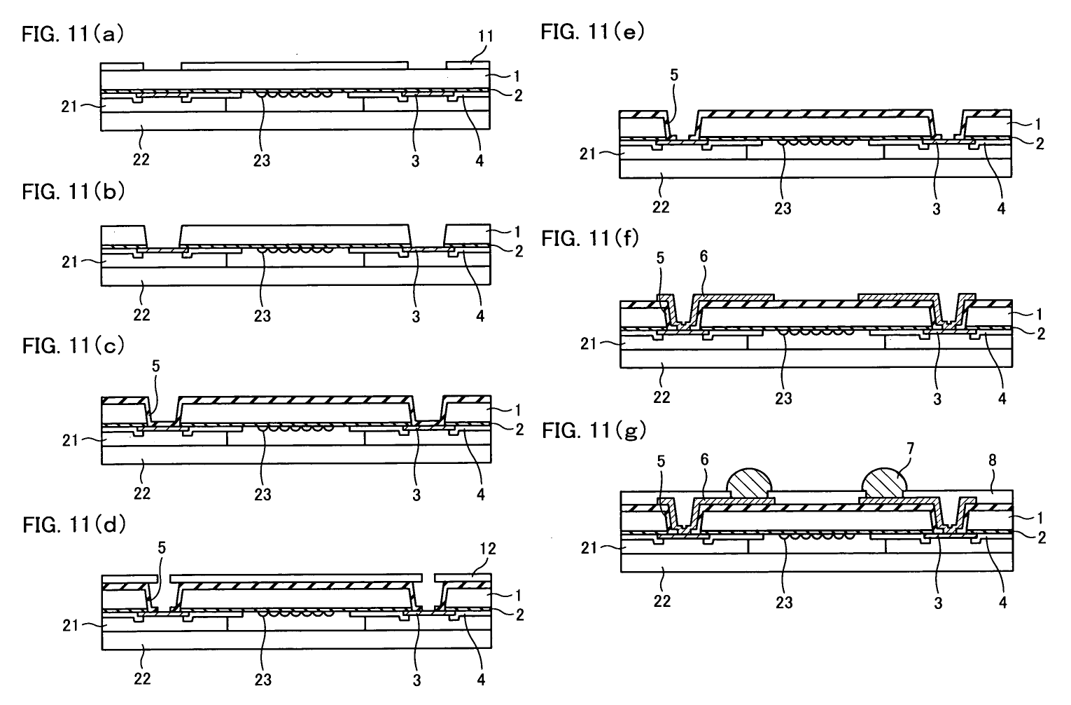

The following describes a method of producing a semiconductor apparatus in accordance with the present embodiment, with reference to FIGS. 11(a) to 11(g).

In the method of the present embodiment, as shown in FIG. 11(a), the bonding layer 21 containing bonding agent is formed on the first surface of the semiconductor substrate 1, on which first surface the first insulating film 2, the metal wiring layer including the electrode pad 3, and the CCD light receiving section 23 are formed. The bonding layer 21 is formed so as to avoid the area where the CCD light receiving section 23 is formed. The reason therefor is that, if the bonding layer 21 is formed on the CCD light receiving section 23, the CCD light receiving section 23 deteriorates optically. Methods of forming the bonding layer 21 are not particularly limited, and any publicly-known methods may be employed to form the bonding layer 21. The bonding layer 21 is formed on the semiconductor substrate 1 by, for example, dispensing, printing, or carrying out photolithography steps to expose and develop photosensitive resin. In some cases, the bonding layer 21 may be formed on the reinforcing plate 22 that is to be adhered to the semiconductor substrate.

Then, to protect the CCD light receiving section 23 including microlenses and the like, the reinforcing plate 22 is adhered to the semiconductor substrate via the bonding layer 21 having a predetermined thickness. The reinforcing plate 22 is employed to protect the CCD light receiving section 23 and to reinforce the semiconductor substrate 1 that is thinned. The thickness of the reinforcing plate 22 is not particularly limited. For example a glass plate having a thickness of 0.5 mm may be employed as the reinforcing plate 23.

Then, the second surface of the semiconductor substrate 1 is polished to adjust the thickness of the semiconductor substrate 1. The thickness of the semiconductor substrate 1 is not particularly limited, and the thickness can be adjusted to a desired thickness in a manner that depends on purposes. For example, the semiconductor substrate 1 can be polished until the thickness of the semiconductor substrate 1 becomes 200 μm. By making the semiconductor substrate 1 as thin as possible, the CCD package is thinned. The area where the CCD light receiving section 23 is formed, however, is an empty area because there is no bonding layer 21. If the semiconductor substrate 1 is polished and becomes too thin when there is such empty area, the semiconductor substrate 1 may break. This problem is solved by polishing the semiconductor substrate 1 in advance by normal back-side polishing until the thickness of the semiconductor substrate 1 becomes 200 μm or below, and then adhering the reinforcing plate 22, on which the bonding layer 21 is formed, to the semiconductor substrate 1.

Then, the resist 11 is applied to the second surface (polished surface) of the semiconductor substrate 1. Thereafter, the resist 11 is exposed and developed so as to form the opening at a part of the first surface, which part corresponds to the electrode pad 3. The resist 11 functions as a mask in dry etching that is carried out to form the through hole in the semiconductor substrate 1.

The foregoing steps are followed by steps in respective production methods according to Embodiments 1 to 6. Specifically, the CCD packages shown in FIGS. 4 to 6 and FIGS. 29 to 31 are produced in accordance with the methods described in Embodiments 1 to 6, respectively. For example FIGS. 11(a) to 11(g) show a method of producing a CCD package employing the semiconductor apparatus described in Embodiment 1. The following describes the method.

First of all, as shown in FIGS. 11(a) and 11(b), dry etching is carried out on the semiconductor substrate 1 with the use of the resist 11 as a mask. As a result, the semiconductor substrate 1 and the first insulating film 2 immediately above the electrode pad 3 are etched. Consequently, the rear surface of the electrode pad 3 is revealed. After the etching, the resist 11 is peeled away.

Then, as shown in FIG. 11(c), the second insulating film 5 is formed on the side surface of the through hole, on the rear surface of the electrode pad 3, and on the second surface of the semiconductor substrate 1. The method of forming the second insulating film is not particularly limited, but it is preferable to employ plasma CVD to form the second insulating film. It is preferable that the second insulating film be a Si oxide film, an oxide film containing boron or phosphorus, a Si oxinitride film, a Si nitride film, a laminated film of the foregoing films, a film made of an electrodeposition material, or a photosensitive resin film. It is preferable that the electrodeposition material be polyimide, epoxy resin, acrylic resin, polyamine, or polycarboxylic acid resin. It is preferable that the photosensitive resin film be a film made of polyimide, epoxy resin, acrylic resin, or silicone resin.

It is also possible to form the second insulating film 5 as follows. A photosensitive resin film in the shape of a sheet is adhered to the second surface of the semiconductor substrate 1 under reduced pressure, and thereafter pressure is applied. Due to the difference in pressure between the outside (pressure applied) and the inside (pressure reduced) of the through hole, the photosensitive resin film in the shape of a sheet is adhered to the second surface of the semiconductor substrate 1 and to the inner wall of the through hole. In the case in which, for example, the photosensitive resin film is employed as the second insulating film 5, even if a notch is formed, the notch is covered by the photosensitive resin film. This makes it possible to maintain insulation between the conductive wiring layer and the semiconductor substrate.

Then, as shown in FIG. 11(d), the resist film 12 is formed to cover the through hole. It is preferable that the resist film 12 be in the shape of a film. The thickness of the resist film 12 is not particularly limited. Materials of the resist film 12 are not particularly limited, and any publicly-known resist films may be employed. For example it is preferable to employ photosensitive resin such as an epoxy group. An opening is formed in the resist film 12. The opening is formed within a part of the resist film 12, which part overlaps, in a direction vertical to a first surface of the semiconductor substrate 1, the bottom surface of the through hole. Methods of forming the opening are not particularly limited, but it is preferable that the opening be formed by photolithography.

Then, as shown in FIG. 11(e), anisotropic dry etching is carried out to eliminate a part of the second insulating film 5 isolating the rear surface of the electrode pad 3 and the conductive wiring from each other. The part of the second insulating film 5 that is eliminated at this time is within the bottom surface of the through hole. The size of the part to be eliminated is not particularly limited, as long as it is smaller than the bottom surface of the through hole. The shape of the part to be eliminated is not particularly limited. The second insulating film 5 is eliminated with the use of the resist film 12 so that only the second insulating film 5 formed on the rear surface of the electrode pad 3 is eliminated without etching the second insulating film 5 formed on the side surface of the through hole. Thereafter, the barrier metal layer (not illustrated) and the seed metal layer (not illustrated) for electrolytic plating are formed on the rear surface of the semiconductor substrate 1. Methods of forming the barrier metal layer and the seed metal layer are not particularly limited, and any publicly-known methods may be employed to form the barrier metal layer and the seed metal layer. For example sputtering or CVD may be employed to form the barrier metal layer and the seed metal layer. In view of thermal adverse effect to the CCD, it is preferable that the barrier metal layer and the seed metal layer be formed by sputtering.

Then, as shown in FIG. 11(f), the conductive wiring layer 6 is formed on the seed metal layer. The conductive wiring layer 6 functions as a rewiring pattern to electrically connect the rear surface of the electrode pad 3 and the external connection terminal 7, which is formed later. Methods of forming the conductive wiring layer 6 are not particularly limited, and any publicly-known methods may be employed. For example, electrolytic copper plating may be employed to form the conductive wiring layer 6.

The following is a concrete method of forming the conductive wiring layer 6. First, resist is applied to the rear surface of the semiconductor substrate 1. The resist is exposed and developed by normal photolithography, thereby forming the rewiring pattern. If it is difficult to apply liquid resist to the semiconductor substrate 1 having the through hole, resist in the form of a film may be used. Thereafter, electrolytic copper plating is carried out, with the seed metal layer being a cathode. As a result, a part of the rewiring pattern increases in thickness, which part corresponds to the opening section of the resist, and the conductive wiring layer is formed. The thickness of the conductive wiring layer is not particularly limited. For example, to mount a solder ball as the external input/output terminal in a following step, it is preferable that the thickness be 10 μm. Thereafter, the resist is eliminated, and unnecessary seed metal layer and unnecessary barrier metal layer are eliminated by etching. It is possible to switch the order of the step of forming the rewiring pattern by photolithography and the step of electrolytic copper plating. Specifically, the conductive wiring layer is formed by electrolytic copper plating or the like, on the seed metal layer formed on the entire rear surface of the semiconductor substrate 1. Then, the resist is exposed and developed by normal photolithography so that the resist that constitutes the rewiring pattern remains, and at the same time, the resist that does not constitute the rewiring pattern is eliminated, thereby forming the rewiring pattern. Thereafter, unnecessary copper-plated layer, unnecessary seed metal layer, and unnecessary barrier metal layer are eliminated by etching.

Then, as shown in FIG. 11(g), the protection film 8 is formed on the entire rear surface of the semiconductor substrate 1 with the use of photosensitive insulating resin. The photosensitive insulating resin is not particularly limited, and any publicly-known photosensitive insulating resin may be employed. Thereafter, an opening is formed in the protection film 8, at which opening the external connection terminal 7 is to be formed. Methods of forming the opening section are not particularly limited, and any publicly-known methods may be employed to form the opening section. For example, the opening section may be formed by exposing and development in photolithography. Thereafter, a solder ball, which is to function as the external connection terminal 7, is mounted on the opening section of the protection film 8, and dicing is carried out to form individual semiconductor chips, whereby the CCD package of the present embodiment is completed.

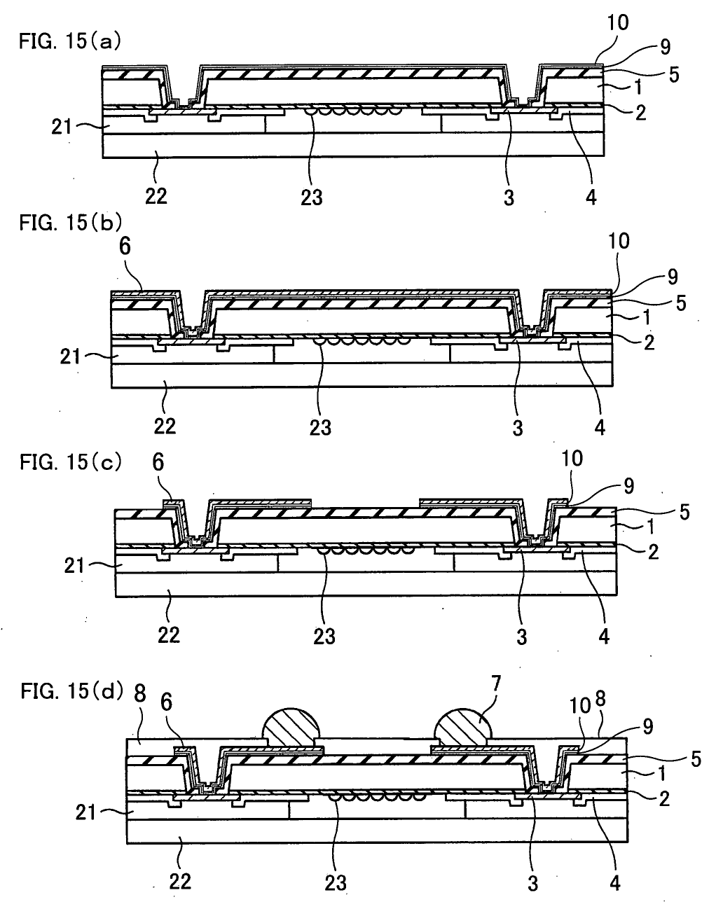

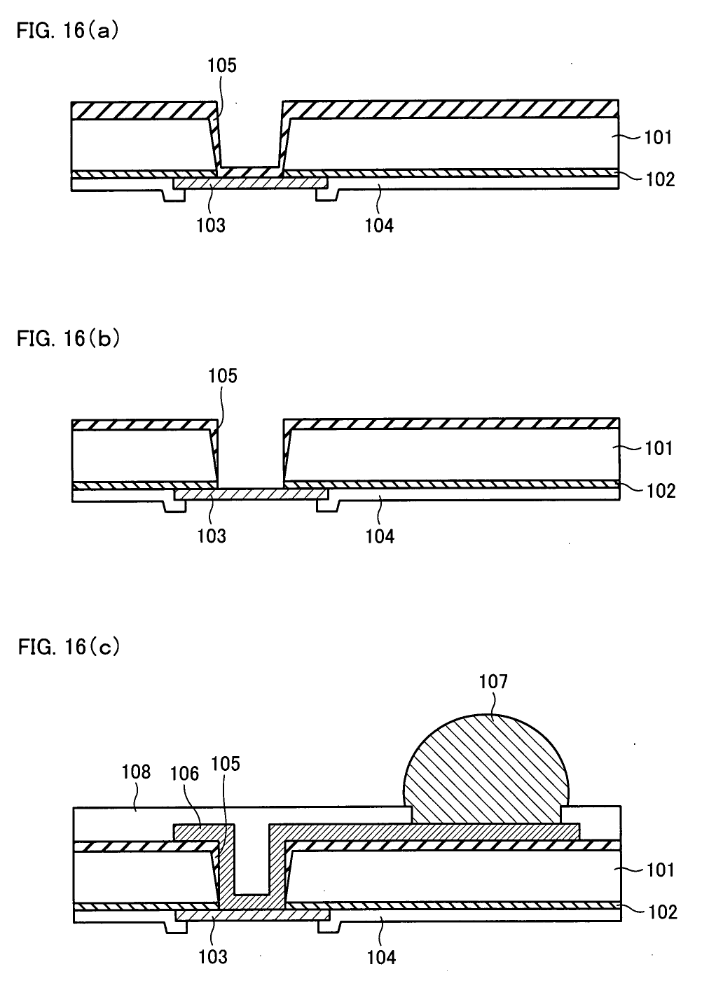

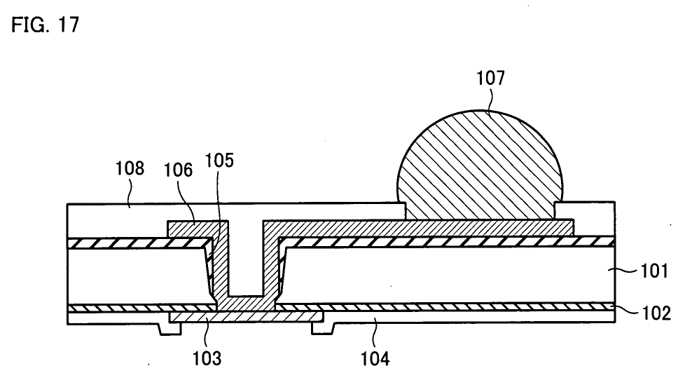

The barrier metal layer and the seed metal layer are now shown in FIGS. 11(e) to 11(g). FIGS. 15(a) to 15(d) show the barrier metal layer 9 and the seed metal layer 10 that are formed in the steps described above. As shown in FIGS. 15(a) to 15(d), a part of the second insulating film 5 is eliminated, and then the barrier metal layer 9 is formed on the rear surface of the semiconductor substrate 1. Thereafter, the seed metal layer 10 is formed on the barrier metal layer 9.

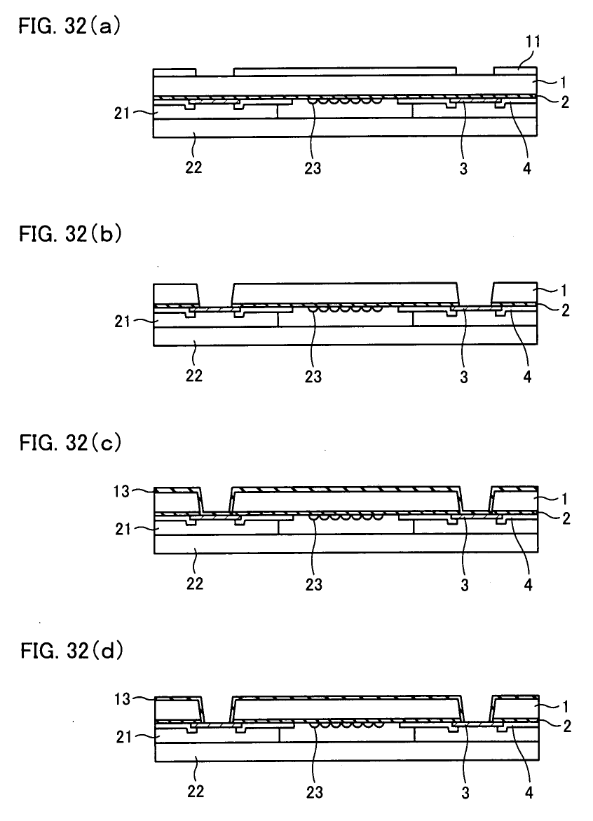

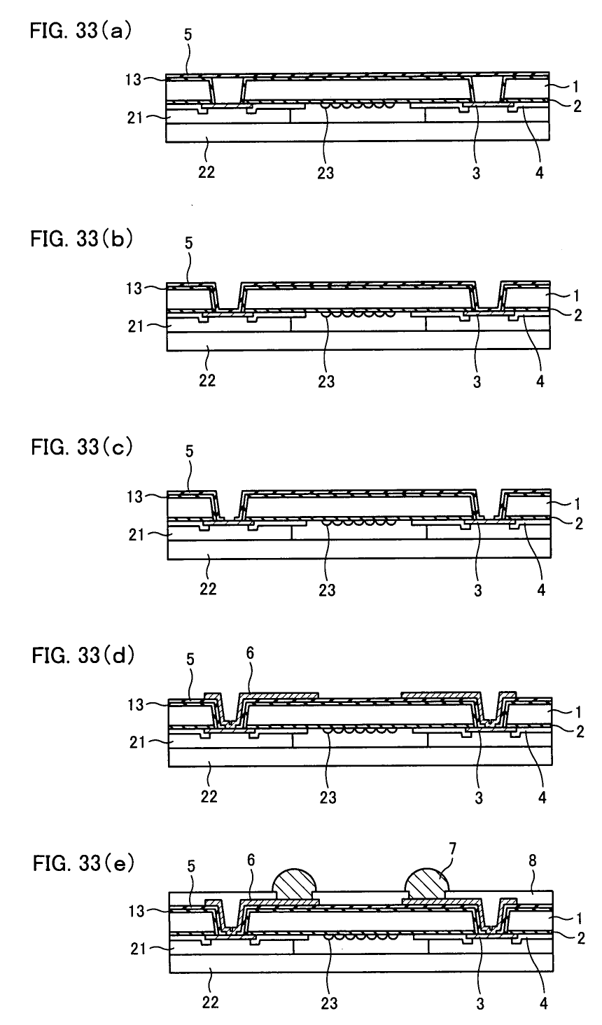

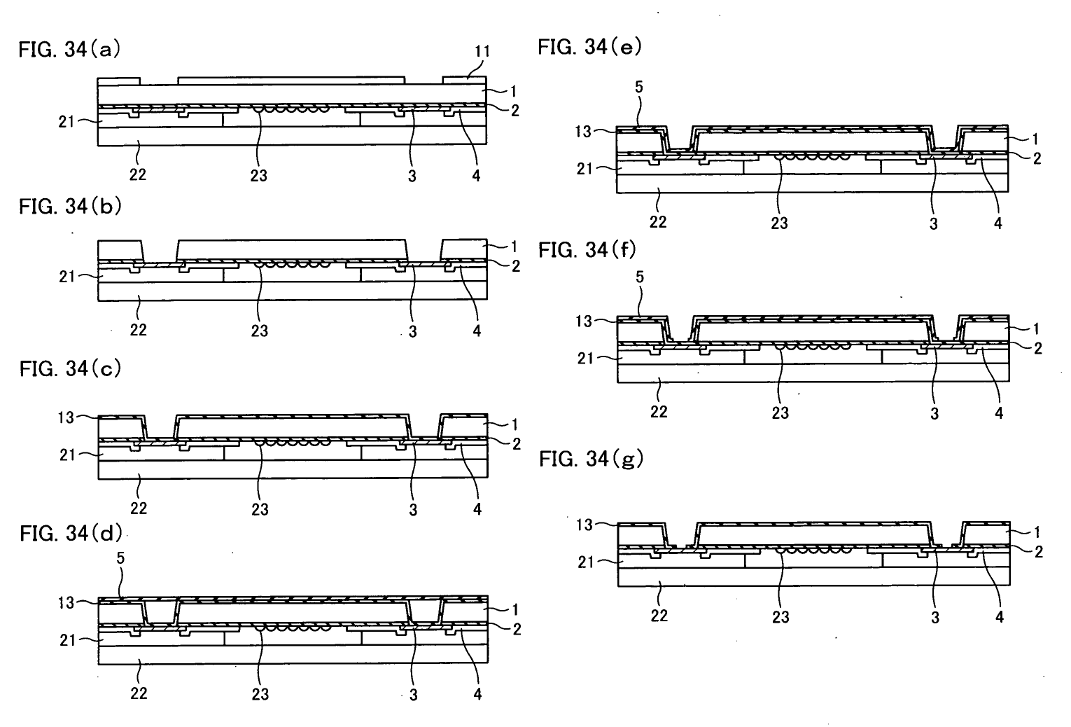

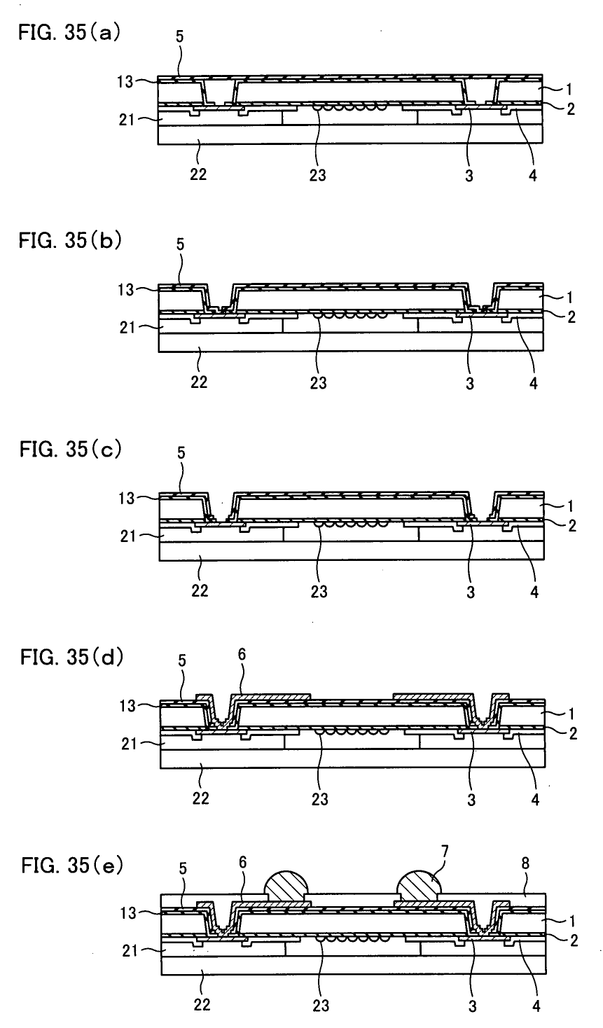

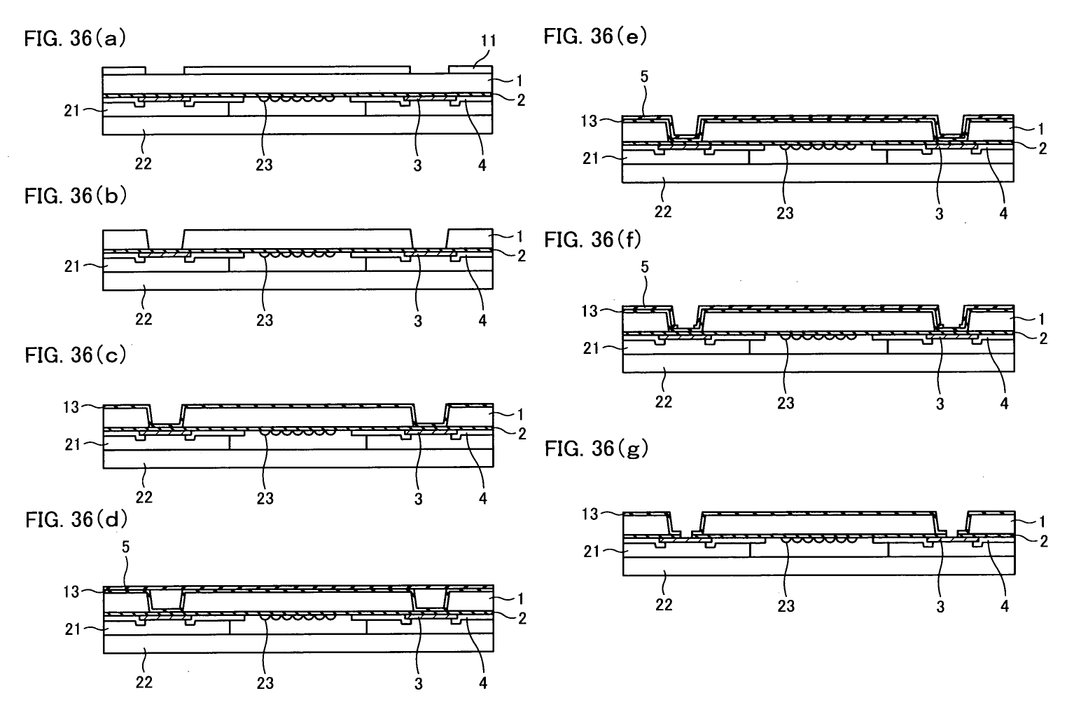

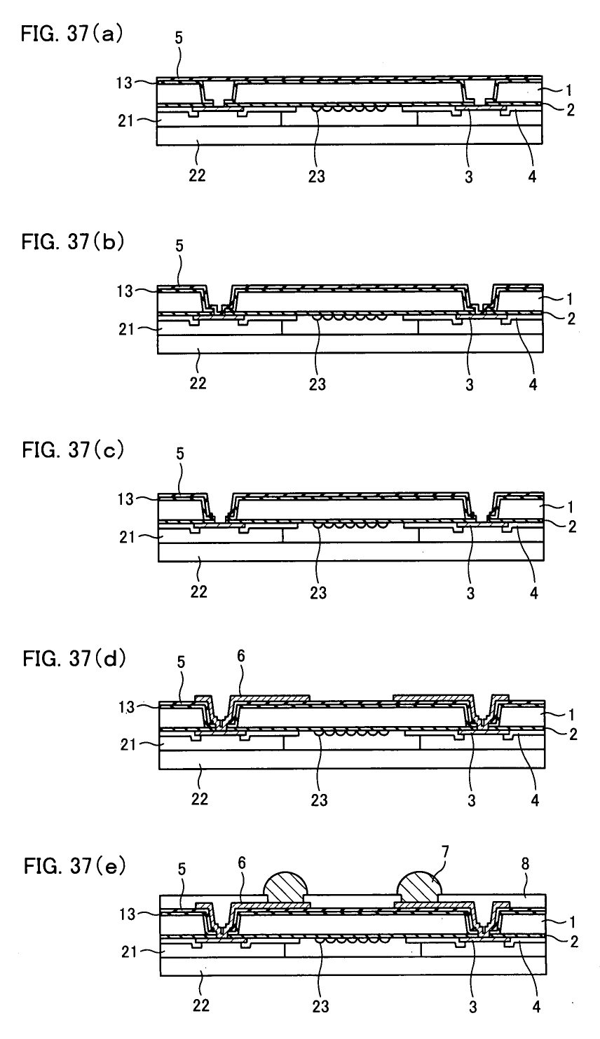

FIGS. 32 and 33 show a method of producing a CCD (Charge Coupled Device) package employing the semiconductor apparatus described in Embodiment 4. FIGS. 34 and 35 show a method of producing a CCD package employing the semiconductor apparatus described in Embodiment 5. FIGS. 36 and 37 show a method of producing a CCD package employing the semiconductor apparatus described in Embodiment 6. The method shown in FIGS. 32 and 33, the method shown in FIGS. 34 and 35, and the method shown in FIGS. 36 and 37 are carried out in accordance with the descriptions of Embodiments 4, 5, and 6, respectively. Therefore, detailed description thereof is omitted here.

As the foregoing describes, according to the semiconductor apparatus of the present invention and the method of producing the semiconductor apparatus, the connection opening formed in at least one of the first insulating film and the second insulating film is formed in such a way as to avoid peripheries of the bottom surface of the through hole. This allows the connection opening to be formed without etching the insulating film formed on the side surface of the through hole. This produces an advantage that a semiconductor apparatus having a highly-reliable through electrode and a method of producing the semiconductor apparatus are provided.

Further, it is also possible to arrange the semiconductor of the present invention and a method of producing the semiconductor apparatus in the following manner.

It is preferable that, in a semiconductor apparatus of the present invention, a third insulating film be formed in between (I) the second insulating film and (ii) the semiconductor substrate and the first insulating film, and an opening be formed at a part of the third insulating film, which part overlaps the connection opening in a direction vertical to the first surface of the semiconductor substrate.

With this structure, the conductive wiring and the semiconductor substrate are insulated from each other by two layers of the second insulating film and the third insulating film. This allows the conductive wiring and the semiconductor substrate to be insulated more assuredly, compared to the case in which the conductive wiring and the semiconductor substrate are insulated only by the second insulating film.

It is preferable in the semiconductor apparatus of the present invention that the third insulating film be any one of: a Si oxide film; an oxide film containing boron or phosphorus; a Si oxinitride film; a Si nitride film; a laminate film of the Si oxide film, the oxide film containing boron or phosphorus, the Si oxinitride film, and the Si nitride film; a film made of an electrodeposition material; and a photosensitive resin film.

It is preferable in the semiconductor apparatus of the present invention that the second insulating film be any one of: a Si oxide film; an oxide film containing boron or phosphorus; a Si oxinitride film; a Si nitride film; a laminate film of the Si oxide film, the oxide film containing boron or phosphorus, the Si oxinitride film, and the Si nitride film; an electrodeposition material; and a photosensitive resin film.

It is preferable in the semiconductor apparatus of the present invention that the photosensitive resin film be a film made of any one of polyimide, epoxy resin, acrylic resin, and silicone resin.

With this structure, the conductive wiring and the semiconductor substrate are insulated from each other. Further, use of an electrodeposition material allows the second insulating film or the third insulating film to be formed only on the conductive material. Further, if the second insulating film and/or the third insulating film are photosensitive resin, it is possible to form the second insulating film and/or the third insulating film having an opening (connection opening) by photolithography. In this case, no etching is carried out in forming an opening in the second insulating film and/or the third insulating film. Thus, the opening is formed at a desired area without eliminating the insulating film under the second insulating film and/or the third insulating film. Because the insulating film under the second insulating film and/or the third insulating film would not be eliminated, the conductive wiring and the semiconductor are insulated more assuredly.

It is preferable that in the semiconductor apparatus of the present invention that the electrodeposition material be any one of polyimide, epoxy resin, acrylic resin, polyamine, and polycarboxylic acid resin.

With this structure, the second insulating film is formed only on the conductive material, and the conductive wiring and the semiconductor substrate are insulated by the second insulating film. For example in a case in which the first insulating film and the semiconductor substrate, such as a Si-substrate, are open, only the semiconductor substrate is a conductive material. Thus, if an electrodeposition material is added to the first insulating film and the semiconductor substrate while current is passed through the semiconductor substrate, the second insulating film is formed only on the semiconductor substrate.

It is preferable in the semiconductor apparatus of the present invention that the first insulating film be any one of: a Si oxide film; an oxide film containing boron or phosphorus; a Si oxinitride film; a Si nitride film; and a laminate film of the Si oxide film, the oxide film containing boron or phosphorus, the Si oxinitride film, and the Si nitride film.

This allows the electrode pad and the semiconductor substrate to be isolated from each other.

It is preferable that the semiconductor apparatus of the present invention include a reinforcing plate, provided on the first surface of the semiconductor substrate, to reinforce the semiconductor substrate.

With this structure, the semiconductor substrate is provided with the reinforcing plate. This makes it possible to increase intensity of the semiconductor substrate, allowing a thin semiconductor substrate to be provided. For example, in the case in which the semiconductor substrate is to be reduced in thickness by polishing or the like, the semiconductor substrate decreases in intensity after the polishing progresses to some extent, and it becomes no longer possible to polish the substrate further. With the reinforcing plate, the semiconductor substrate increases in intensity, and therefore it becomes possible to polish the substrate further. This makes it possible to provide a thin semiconductor substrate. Many advantages are produced if the semiconductor substrate is thin. For example if the semiconductor substrate is thick, etching requires a longer time in forming the through hole in the semiconductor substrate. This causes the costs to increase and makes it difficult to control the shape of the hole. This problem is avoidable by reducing the thickness of the semiconductor substrate.

It is preferable that the semiconductor apparatus of the present invention include a pixel area, in between the semiconductor substrate and the reinforcing plate, to receive light.

This allows the semiconductor apparatus of the present invention to be structured in the form of a CCD.

It is preferable in the semiconductor apparatus of the present invention that the reinforcing plate transmit light.

With this structure, light is incident on the pixel area efficiently through the reinforcing plate. Therefore, in the case in which the semiconductor apparatus of the present invention is structured in the form of a CCD, the reinforcing plate reinforces the semiconductor substrate without interrupting light to be incident on the pixel area.

It is preferable in a method of producing the semiconductor apparatus in accordance with the present invention that the step of forming the connection opening include: forming, on the second insulating film formed on the second surface of the semiconductor substrate, a resist film to cover the through hole; forming an etching mask by forming an opening within a part of the resist film, which part overlaps, in a direction vertical to the first surface of the semiconductor substrate, the bottom surface of the through hole; and eliminating, by anisotropic dry etching with the etching mask, the second insulating film formed so as to overlap the bottom surface of the through hole, and forming the connection opening to the electrode pad in such a way as to avoid a periphery of the bottom surface of the through hole.

With this structure, the second insulating film formed so as to overlap the bottom surface of the through hole is eliminated by anisotropic dry etching with the use of a resist film having an opening smaller than the bottom surface of the through hole. Thus, only the second insulating film formed so as to overlap the bottom surface of the through hole, without eliminating the second insulating film formed on the inner side surface of the through hole. Thus, the semiconductor substrate or the like is not revealed from the inner side surface of the through hole, and insulation is maintained suitably between the conductive wiring and the semiconductor substrate inside of the through hole. Further, with the structure, only the insulating film formed on the bottom surface of the through hole even when the side surface of the through hole is formed at an angle of 90 degrees with respect to the bottom surface of the through hole. This allows the semiconductor apparatus to be small.

It is preferable in the method of the present invention that the second insulating film be any one of: a Si oxide film; an oxide film containing boron or phosphorus; a Si oxinitride film; a Si nitride film; a laminate film of the Si oxide film, the oxide film containing boron or phosphorus, the Si oxinitride film, and the Si nitride film; and a film made of an electrodeposition material.

This allows the conductive wiring and the semiconductor substrate to be isolated from each other.

It is preferable in the method of the present invention that the electrodeposition material be any one of polyimide, epoxy resin, acrylic resin, polyamine, and polycarboxylic acid resin.

With this structure, the second insulating film is formed only on the conductive material, and the conductive wiring and the semiconductor substrate are insulated from each other by the second insulating film. For example there may be a case in which the electrode pad and the semiconductor substrate, such as a Si-substrate, are open. The electrode pad and the semiconductor substrate are both conductive materials. Accordingly, if an electrodeposition material is added to the semiconductor substrate and the electrode pad while current is passed through the semiconductor substrate and the electrode pad, the second insulating film is formed on the semiconductor substrate and on the electrode pad.

It is preferable in the method of the present invention that the second insulating film be a photosensitive resin film, and the step of forming the connection opening include forming the connection opening to the electrode pad by carrying out, on the second insulating film formed so as to overlap the bottom surface of the through hole, photolithography to eliminate the second insulating film that is not on a periphery of the bottom surface of the through hole.

With this structure, the second insulating film having a desired opening is formed. No etching is carried out in forming the opening. This makes it is possible to form a desired opening in the second insulating film without eliminating that another insulating film even when another insulating film is formed under the second insulating film. Therefore, the electrode pad and the semiconductor substrate are isolated from each other more assuredly.

It is preferable in the method of the present invention that the photosensitive resin film be a film made of any one of polyimide, epoxy resin, acrylic resin, and silicone resin.

With this structure, the second insulating film having a desired opening is formed easily with the use of the photosensitive resin film.

It is preferable that the method of the present invention include, between the step of forming the through hole in the semiconductor substrate and the step of forming the second insulating film, the steps of: forming a third insulating film on the side surface of the through hole, on the bottom surface of the through hole, and on the second surface of the semiconductor substrate; and eliminating, by etching, a part of the third insulating film, which part overlaps, in a direction vertical to the first surface of the semiconductor substrate, the connection opening.

With this structure, the conductive wiring and the semiconductor substrate are insulated from each other by two layers of the second insulating film and the third insulating film. Therefore, the conductive wiring and the semiconductor substrate are insulated more assuredly, compared to the case in which the conductive wiring and the semiconductor substrate are insulated only by the second insulating film.

It is preferable in the method of the present invention that the third insulating film be any one of: a Si oxide film; an oxide film containing boron or phosphorus; a Si oxinitride film; a Si nitride film; and a laminate film of the Si oxide film, the oxide film containing boron or phosphorus, the Si oxinitride film, and the Si nitride film.

This allows the conductive wiring and the semiconductor substrate to be isolated from each other.

It is preferable in the method of the present invention that step of forming the second insulating film on the side surface of the through hole, on the bottom surface of the through hole, and on the second surface of the semiconductor substrate, include: adhering, under reduced pressure, the second insulating film to the second surface of the semiconductor substrate to cover the through hole; and adhering the second insulating film to the side surface of the through hole and to the bottom surface of the through hole by applying pressure to an outside of the through hole while an inside of the through hole is reduced in pressure, the outside and the inside of the through hole being separated by the second insulating film.

With this structure, the pressure inside of the through hole separated by the second insulating film is reduced, and pressure is applied to the outside of the through hole. Consequently, the second insulating film is drawn to the inside of the through hole. As a result, the second insulating film is adhered to the side surface and the bottom surface of the through hole. Further, it is possible to create, at one time, a difference in pressure between the inside and the outside of a large number of through holes. This allows the second insulating film to be adhered to the large number of through holes at the same time.

It is preferable in the method of the present invention that the step of eliminating the third insulating film include: forming a photosensitive resin film, for masking, to cover the through hole; carrying out photolithography on the photosensitive resin film to form an etching mask having an opening within a part of the etching mask, which part overlaps, in a direction vertical to the first surface of the semiconductor substrate, the bottom surface of the through hole; and eliminating, by anisotropic dry etching with the etching mask, a part of the third insulating film formed on the bottom surface of the through hole, which part is not on the periphery of the bottom surface of the through hole.

With this structure, only a part of the third insulating film formed on the bottom surface of the through hole is eliminated, which part is not on the periphery of the bottom surface of the through hole. This allows the conductive wiring and the semiconductor substrate to be insulated from each other.

It is preferable in the method of the present invention that the photosensitive resin film for masking be formed, under reduced pressure, to cover the through hole, and then adhered to the side surface of the through hole and to the bottom surface of the through hole by applying pressure to an outside of the through hole while an inside of the through hole is reduced in pressure, the outside and the inside of the through hole being separated by the photosensitive resin film.

With this structure, the pressure inside of the through hole separated by the photosensitive resin for masking is reduced, and pressure is applied to the outside of the through hole. Consequently, the photosensitive resin film for masking is drawn to the inside of the through hole. As a result, the photosensitive resin for masking is adhered to the side surface and the bottom surface of the through hole. Further, it is possible to create, at one time, a difference in pressure between the inside and the outside of a large number of through holes. This allows the photosensitive resin film for masking to be adhered to the large number of through holes at the same time. If the photosensitive resin film for masking is adhered to the inside of the through hole, the distance between the etching mask and the third insulating film becomes short. If the distance between the etching mask and the third insulating film is short, only a desired area in the third insulating film is eliminated precisely by anisotropic dry etching.

It is preferable in the method of the present invention that the photosensitive resin film for masking be made of any one of polyimide, epoxy resin, acrylic resin, and silicone resin.

With this structure, an etching mask having a desired opening is formed easily with the use of the photosensitive resin for masking.

It is preferable in the method of the present invention that the second insulating film be any one of: a Si oxide film; an oxide film containing boron or phosphorus; a Si oxinitride film; a Si nitride film; and a laminate film of the Si oxide film, the oxide film containing boron or phosphorus, the Si oxinitride film, and the Si nitride film.

This allows the conductive wiring and the semiconductor substrate to be isolated from each other.

It is preferable in the method of the present invention that the second insulating film be made of an electrodeposition material.

It is preferable in the method of the present invention that the electrodeposition material be any one of polyimide, epoxy resin, acrylic resin, polyamine, and polycarboxylic acid resin.

With this structure, the second insulating film is formed only on the conductive material such as the semiconductor substrate. For example in a case in which the first insulating film and the semiconductor substrate, such as a Si-substrate, are open, only the semiconductor substrate is a conductive material. Therefore, if an electrodeposition material is added to the first insulating film and the semiconductor substrate while current is passed through the semiconductor substrate, the second insulating film is formed only on the semiconductor substrate.

It is preferable in the method of the present invention that each of the second insulating film and the photosensitive resin film for masking be a film made of any one of polyimide, epoxy resin, acrylic resin, and silicone resin.

With this structure, the etching mask and the second insulating film having a desired opening are formed.

It is preferable in the method of the present invention that the third insulating film be any one of: a Si oxide film; an oxide film containing boron or phosphorus; a Si oxinitride film; a Si nitride film; and a laminate film of the Si oxide film, the oxide film containing boron or phosphorus, the Si oxinitride film, and the Si nitride film.

This allows the conductive wiring and the semiconductor substrate to be isolated from each other.

It is preferable in the method of the present invention that the photosensitive resin film for masking be formed, under reduced pressure, so as to cover the through hole, and then adhered to the side surface of the through hole and to the bottom surface of the through hole by applying pressure to an outside of the through hole while an inside of the through hole is reduced in pressure, the outside and the inside of the through hole being separated by the photosensitive resin film.

With this structure, the pressure inside of the through hole separated by the photosensitive resin for masking is reduced, and pressure is applied to the outside of the through hole. Consequently, the photosensitive resin film for masking is drawn to the inside of the through hole. As a result, the photosensitive resin for masking is adhered to the side surface and the bottom surface of the through hole. Further, it is possible to create, at one time, a difference in pressure between the inside and the outside of a large number of through holes. This allows the photosensitive resin film for masking to be adhered to the large number of through holes at the same time.

It is preferable in the method of the present invention that the step of forming the second insulating film on the third insulating film include: adhering, under reduced pressure, the second insulating film so as to cover the through hole; and adhering the second insulating film to the side surface of the through hole and to the bottom surface of the through hole by applying pressure to an outside of the through hole while an inside of the through hole is reduced in pressure, the outside and the inside of the through hole being separated by the second insulating film.

With this structure, the pressure inside of the through hole separated by the second insulating film is reduced, and the pressure is applied to the outside of the through hole. Consequently, the second insulating film is drawn to the inside of the through hole. As a result, the second insulating film is adhered to the side surface and the bottom surface of the through hole. Further, it is possible to create, at one time, a difference in pressure between the inside and the outside of a large number of through holes. This allows the second insulating film to be adhered to the large number of through holes at the same time.

It is preferable in the method of the present invention that the first insulating film be formed of any one of: a Si oxide film; an oxide film containing boron or phosphorus; a Si oxinitride film; a Si nitride film; and a laminate film of the Si oxide film, the oxide film containing boron or phosphorus, the Si oxinitride film, and the Si nitride film.

This allows the electrode pad and the semiconductor substrate to be isolated from each other.

It is preferable in the method of the present invention that the through hole be formed by anisotropic plasma etching.

This allows forming a desired through hole.

It is preferable in the method of producing a semiconductor apparatus in accordance with the present invention that an opening to be formed in the resist film in the form of a film be formed by photolithography.

This makes it possible to easily form, at an area on the resist film covering the through hole, an opening smaller than the bottom surface of the through hole.

It is preferable in the method of the present invention that, in the step of forming the through hole in the semiconductor substrate, a reinforcing plate be provided, on the first surface of the semiconductor substrate, to reinforce the semiconductor substrate.

With this structure, the semiconductor substrate is provided with the reinforcing plate. This makes it possible to increase intensity of the semiconductor substrate. Therefore, in the case in which the thickness of the semiconductor substrate is to be reduced by polishing or the like, because the semiconductor substrate is strengthened, it is possible to thin the semiconductor substrate by the polishing. This makes it possible to provide a thin semiconductor substrate.

The semiconductor apparatus of the present invention includes a through electrode that is highly reliable. The present invention provides a method of producing the semiconductor apparatus. Accordingly, the present invention is applicable to semiconductor apparatuses and production of components of the semiconductor apparatuses.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A semiconductor apparatus, comprising:
a semiconductor substrate having a through hole formed through both surfaces of the semiconductor substrate;
an electrode pad provided, on a first surface of the semiconductor substrate, so as to cover the through hole;
an external connection terminal provided on a second surface of the semiconductor substrate;
a conductive wiring passing through the through hole and allowing conduction between the electrode pad and the external connection terminal;
a first insulating film provided on the first surface of the semiconductor substrate to insulate the semiconductor substrate from the electrode pad; and
a second insulating film provided on the second surface of the semiconductor substrate and on an inner surface of the through hole to insulate the semiconductor substrate from the conductive wiring,
the conductive wiring being connected to the electrode pad via a connection opening formed in at least one of the first insulating film and the second insulating film that are provided in such a way that at least a part of the first insulating film and a part of the second insulating film overlap, in a direction vertical to the first surface of the semiconductor substrate, a bottom surface of the through hole, and
the connection opening being formed in such a way as to avoid a periphery of the bottom surface of the through hole.

2. The semiconductor apparatus of claim 1, further comprising:
a third insulating film formed in between (i) the second insulating film and the (ii) the semiconductor substrate and the first insulating film,
the third insulating film having an opening in a part of the third insulating film, which part overlaps, in the direction vertical to the first surface of the semiconductor substrate, the connection opening.

3. The semiconductor apparatus of claim 2, wherein the third insulating film is any one of: a Si oxide film; an oxide film containing boron or phosphorus; a Si oxinitride film; a Si nitride film; a laminate film of the Si oxide film, the oxide film containing boron or phosphorus, the Si oxinitride film, and the Si nitride film; a film made of an electrodeposition material; and a photosensitive resin film.

4. The semiconductor apparatus of claim 1, wherein the second insulating film is any one of: a Si oxide film;
an oxide film containing boron or phosphorus; a Si oxinitride film; a Si nitride film; a laminate film of the Si oxide film, the oxide film containing boron or phosphorus, the Si oxinitride film, and the Si nitride film; an electrodeposition material; and a photosensitive resin film.

5. The semiconductor apparatus of claim 3, wherein the photosensitive resin film is a film made of any one of polyimide, epoxy resin, acrylic resin, and silicone resin.

6. The semiconductor apparatus of claim 3, wherein the electrodeposition material is any one of polyimide, epoxy resin, acrylic resin, polyamine, and polycarboxylic acid resin.

7. The semiconductor apparatus of claim 1, wherein the first insulating film is any one of: a Si oxide film; an oxide film containing boron or phosphorus; a Si oxinitride film; a Si nitride film; and a laminate film of the Si oxide film, the oxide film containing boron or phosphorus, the Si oxinitride film, and the Si nitride film.

8. The semiconductor apparatus of claim 1, further comprising a reinforcing plate, provided on the first surface of the semiconductor substrate, to reinforce the semiconductor substrate.

9. The semiconductor apparatus of claim 8, further comprising a pixel area, in between the semiconductor substrate and the reinforcing plate, to receive light.

10. The semiconductor apparatus of claim 9, wherein the reinforcing plate transmits light.

11. A method of producing a semiconductor apparatus, comprising the steps of:
forming an electrode pad on a first surface of a semiconductor substrate via a first insulating film;
forming a through hole in the semiconductor substrate from a second surface, which is positioned opposite to the first surface, of the semiconductor substrate to the electrode pad formed on the first surface;
forming a second insulating film on a side surface of the through hole, on a bottom surface of the through hole, and on the second surface of the semiconductor substrate to insulate the semiconductor substrate from a conductive wiring;
eliminating the second insulating film formed so as to overlap the bottom surface of the through hole, and forming a connection opening to the electrode pad in such a way as to avoid a periphery of the bottom surface of the through hole; and
forming the conductive wiring to electrically connect the electrode pad to an external connection terminal.

12. The method of claim 11, wherein the step of forming the connection opening includes:
forming, on the second insulating film formed on the second surface of the semiconductor substrate, a resist film to cover the through hole;
forming an etching mask by forming an opening within a part of the resist film, which part overlaps, in a direction vertical to the first surface of the semiconductor substrate, the bottom surface of the through hole; and
eliminating, by anisotropic dry etching with the etching mask, the second insulating film formed so as to overlap the bottom surface of the through hole, and forming the connection opening to the electrode pad in such a way as to avoid a periphery of the bottom surface of the through hole.

13. The method of claim 12, wherein the second insulating film is any one of: a Si oxide film; an oxide film containing boron or phosphorus; a Si oxinitride film; a Si nitride film; a laminate film of the Si oxide film, the oxide film containing boron or phosphorus, the Si oxinitride film, and the Si nitride film; and a film made of an electrodeposition material.

14. The method of claim 13, wherein the electrodeposition material is any one of polyimide, epoxy resin, acrylic resin, polyamine, and polycarboxylic acid resin.

15. The method of claim 11, wherein:
the second insulating film is a photosensitive resin film; and
the step of forming the connection opening includes forming the connection opening to the electrode pad by carrying out, on the second insulating film formed so as to overlap the bottom surface of the through hole, photolithography to eliminate the second insulating film that is not on a periphery of the bottom surface of the through hole.

16. The method of claim 15, wherein the photosensitive resin film is a film made of any one of polyimide, epoxy resin, acrylic resin, and silicone resin.

17. The method of claim 11, further comprising, between the step of forming the through hole in the semiconductor substrate and the step of forming the second insulating film, the steps of:
forming a third insulating film on the side surface of the through hole, on the bottom surface of the through hole, and on the second surface of the semiconductor substrate; and
eliminating, by etching, a part of the third insulating film, which part overlaps, in a direction vertical to the first surface of the semiconductor substrate, the connection opening.

18. The method of claim 17, wherein the third insulating film is any one of: a Si oxide film; an oxide film containing boron or phosphorus; a Si oxinitride film; a Si nitride film; and a laminate film of the Si oxide film, the oxide film containing boron or phosphorus, the Si oxinitride film, and the Si nitride film.

19. The method of claim 11, wherein the step of forming the second insulating film on the side surface of the through hole, on the bottom surface of the through hole, and on the second surface of the semiconductor substrate, includes:
adhering, under reduced pressure, the second insulating film to the second surface of the semiconductor substrate to cover the through hole; and
adhering the second insulating film to the side surface of the through hole and to the bottom surface of the through hole by applying pressure to an outside of the through hole while an inside of the through hole is reduced in pressure, the outside and the inside of the through hole being separated by the second insulating film.

20. The method of claim 17, wherein the step of eliminating the third insulating film includes:
forming a photosensitive resin film, for masking, to cover the through hole;
carrying out photolithography on the photosensitive resin film to form an etching mask having an opening within a part of the etching mask, which part overlaps, in a direction vertical to the first surface of the semiconductor substrate, the bottom surface of the through hole; and
eliminating, by anisotropic dry etching with the etching mask, a part of the third insulating film formed on the bottom surface of the through hole, which part is not on the periphery of the bottom surface of the through hole.

21. The method of claim 20, wherein the photosensitive resin film for masking is formed, under reduced pressure, to cover the through hole, and then adhered to the side surface of the through hole and to the bottom surface of the through hole by applying pressure to an outside of the through hole while an inside of the through hole is reduced in pressure, the outside and the inside of the through hole being separated by the photosensitive resin film.

22. The method of claim 20, wherein the photosensitive resin film is made of any one of polyimide, epoxy resin, acrylic resin, and silicone resin.

23. The method of claim 11, wherein the first insulating film is any one of: a Si oxide film; an oxide film containing boron or phosphorus; a Si oxinitride film; a Si nitride film; and a laminate film of the Si oxide film, the oxide film containing boron or phosphorus, the Si oxinitride film, and the Si nitride film.

24. The method of claim 11, wherein the through hole is formed by anisotropic plasma etching.

25. The method of claim 12, wherein the opening is formed in a resist film by photolithography.

26. The method of claim 11, wherein, in the step of forming the through hole in the semiconductor substrate, a reinforcing plate is provided, on the first surface of the semiconductor substrate, to reinforce the semiconductor substrate.

27. A method of producing a semiconductor apparatus, comprising the steps of:
forming an electrode pad on a first surface of a semiconductor substrate via a first insulating film;
forming a through hole in the semiconductor substrate from a second surface, which is positioned opposite to the first surface, of the semiconductor substrate to the first insulating film;
forming a second insulating film on a side surface of the through hole, on a bottom surface of the through hole, and on the second surface of the semiconductor substrate to insulate the semiconductor substrate from a conductive wiring;
forming, on the second insulating film formed on the second surface of the semiconductor substrate, a resist film so as to cover the through hole;
forming an etching mask by forming an opening within a part of the resist film, which part overlaps, in a direction vertical to the first surface of the semiconductor substrate, the bottom surface of the through hole;
eliminating, by anisotropic dry etching with the etching mask, the first insulating film and the second insulating film that are formed so as to overlap the bottom surface of the through hole, and forming a connection opening to the electrode pad in such a way as to avoid a periphery of the bottom surface of the through hole; and
forming the conductive wiring to electrically connect the electrode pad to an external connection terminal.

28. The method of claim 27, wherein the second insulating film is any one of: a Si oxide film; an oxide film containing boron or phosphorus; a Si oxinitride film; a Si nitride film; and a laminate film of the Si oxide film, the oxide film containing boron or phosphorus, the Si oxinitride film, and the Si nitride film.

29. The method of claim 27, wherein the first insulating film is formed of any one of: a Si oxide film; an oxide film containing boron or phosphorus; a Si oxinitride film; a Si nitride film; or a laminate film of the Si oxide film, the oxide film containing boron or phosphorus, the Si oxinitride film, and the Si nitride film.

30. The method of claim 27, wherein the through hole is formed by anisotropic plasma etching.

31. The method of claim 27, wherein the opening is formed in the resist film by photolithography.

32. The method of claim 27, wherein, in the step of forming the through hole in the semiconductor substrate, a reinforcing plate is provided, on the first surface of the semiconductor substrate, to reinforce the semiconductor substrate.

33. A method of producing a semiconductor apparatus, comprising the steps of:
forming an electrode pad on a first surface of a semiconductor substrate via a first insulating film;
forming a through hole in the semiconductor substrate from a second surface, which is positioned opposite to the first surface, of the semiconductor substrate to the first insulating film formed on the first surface;
forming a second insulating film on a side surface of the through hole, on a bottom surface of the through hole, and on the second surface of the semiconductor substrate to insulate the semiconductor substrate from a conductive wiring;
forming, on the second insulating film formed on the second surface of the semiconductor substrate, a resist film so as to cover the through hole;
forming an etching mask by forming an opening within a part of the resist film, which part overlaps, in a direction vertical to the first surface of the semiconductor substrate, the bottom surface of the through hole;
eliminating, by anisotropic dry etching with the etching mask, the first insulating film formed so as to overlap the bottom surface of the through hole, and forming a connection opening to the electrode pad in such a way as to avoid a periphery of the bottom surface of the through hole; and
forming the conductive wiring to electrically connect the electrode pad to an external connection terminal.

34. The method of claim 33, wherein the second insulating film is made of an electrodeposition material.

35. The method of claim 34, wherein the electrodeposition material is any one of polyimide, epoxy resin, acrylic resin, polyamine, and polycarboxylic acid resin.

36. The method of claim 33, wherein the first insulating film is formed of any one of: a Si oxide film; an oxide film containing boron or phosphorus; a Si oxinitride film; a Si nitride film; or a laminate film of the Si oxide film, the oxide film containing boron or phosphorus, the Si oxinitride film, and the Si nitride film.

37. The method of claim 33, wherein the through hole is formed by anisotropic plasma etching.

38. The method of claim 33, wherein the opening is formed in the resist film by photolithography.

39. The method of claim 33, wherein, in the step of forming the through hole in the semiconductor substrate, a reinforcing plate is provided, on the first surface of the semiconductor substrate, to reinforce the semiconductor substrate.

40. A method of producing a semiconductor apparatus, comprising the steps of:
forming an electrode pad on a first surface of a semiconductor substrate via a first insulating film;
forming a through hole in the semiconductor substrate from a second surface, which is positioned opposite to the first surface, of the semiconductor substrate to the first insulating film formed on the first surface;
forming a third insulating film on a side surface of the through hole, on a bottom surface of the through hole, and on the second surface of the semiconductor substrate to insulate the semiconductor substrate from a conductive wiring;
forming, on the third insulating film, a photosensitive resin film, for masking, so as to cover the through hole;
carrying out photolithography on the photosensitive resin film to form an etching mask having an opening within a part of the etching mask, which part overlaps, in a direction vertical to the first surface of the semiconductor substrate, the bottom surface of the through hole;
eliminating, by anisotropic dry etching with the etching mask, a laminate film of the first insulating film and the third insulating film, which laminate film is formed so as to overlap the bottom surface of the through hole, and forming an opening to the electrode pad in such a way as to avoid a periphery of the bottom surface of the through hole;
forming, after the etching mask is peeled away, a second insulating film on the third insulating film, the second insulating film being formed of a photosensitive resin film;
forming the connection opening to the electrode pad by carrying out, on the second insulating film formed so as to overlap the bottom surface of the through hole, photolithography to eliminate the second insulating film that is not on a periphery of the bottom surface of the through hole; and
forming the conductive wiring to electrically connect the electrode pad to an external connection terminal.

41. The method of claim 40, wherein each of the second insulating film and the photosensitive resin film is a film made of any one of polyimide, epoxy resin, acrylic resin, and silicone resin.

42. The method of claim 40, wherein the third insulating film is any one of: a Si oxide film; an oxide film containing boron or phosphorus; a Si oxinitride film; a Si nitride film; and a laminate film of the Si oxide film, the oxide film containing boron or phosphorus, the Si oxinitride film, and the Si nitride film.

43. The method of claim 40, wherein the photosensitive resin film for masking is formed, under reduced pressure, so as to cover the through hole, and then adhered to the side surface of the through hole and to the bottom surface of the through hole by applying pressure to an outside of the through hole while an inside of the through hole is reduced in pressure, the outside and the inside of the through hole being separated by the photosensitive resin film.

44. The method of claim 40, wherein the step of forming the second insulating film on the third insulating film includes:
adhering, under reduced pressure, the second insulating film so as to cover the through hole; and
adhering the second insulating film to the side surface of the through hole and to the bottom surface of the through hole by applying pressure to an outside of the through hole while an inside of the through hole is reduced in pressure, the outside and the inside of the through hole being separated by the second insulating film.

45. The method of claim 40, wherein the first insulating film is formed of any one of: a Si oxide film; an oxide film containing boron or phosphorus; a Si oxinitride film; a Si nitride film; and a laminate film of the Si oxide film, the oxide film containing boron or phosphorus, the Si oxinitride film, and the Si nitride film.

46. The method of claim 40, wherein the through hole is formed by anisotropic plasma etching.

47. The method of claim 40, wherein, in the step of forming the through hole in the semiconductor substrate, a reinforcing plate is provided, on the first surface of the semiconductor substrate, to reinforce the semiconductor substrate.
